(19) United States
(12) Patent Application Publication
(10) Pub. No.: US 2011/0265861 A1
(43) Pub. Date: Nov. 3, 2011

(54) FASTENING STRUCTURE FOR A LARGE SOLAR MODULE, AND SOLAR MODULE

(75) Inventors: Anton Näbauer, Munchen (DE); Klaus Gehrlicher, Haar (DE); Andreas Raspini, Hohenkirchen (DE)

(73) Assignee: GEHRLICHER SOLAR AG, Neustadt/Coburg (DE)

(21) Appl. No.: 13/054,096

(22) PCT Filed: Jul. 10, 2009
(86) PCT No.: PCT/EP2009/005014

§ 371 Date: Mar. 1, 2011

(30) Foreign Application Priority Data
Jul. 14, 2008 (DE) 10 2008 032 985.1
Oct. 20, 2008 (DE) 10 2008 052 368.2
May 4, 2009 (DE) 10 2009 019 829.6

(51) Int. Cl. H01L 31/048; F16M 11/04; H01L 23/12

(52) U.S. Cl. 136/251; 248/440.1; 248/121

(57) ABSTRACT

Structure for fixing a large solar module (12) to a substructure (14), having at least two retaining profile-members (26) which can be fixed to a component from the solar module (12) and substructure (14) at the rear, characterised by at least two receiving profile-members (60) which can be fixed to the other component from the solar module (12) and substructure (14) in a mutual relative position which corresponds to the relative position of the retaining profile-members (26), the retaining profile-member (26) and the receiving profile-member (60) having a mutually complementary profile shape so that the retaining profile-member (26) can be received in a substantially positive-locking manner in the receiving profile-member (60), there being provided, on at least one pair comprising a mutually engaging retaining profile-member (26) and receiving profile-member (60), mutually corresponding engagement formations, by means of which the retaining profile-member (26) and the receiving profile-member (60) engage with each other in a locking manner.

### TECHNICAL FIELD

The present invention relates to a structure for fixing a large solar module to a substructure, having at least two retaining profile-members which can be fixed to a component from the solar module and substructure.

### BACKGROUND

The use of photovoltaic solar modules has increased considerably over recent years. Owing to the ever-increasing popularity of using solar energy, solar modules are increasingly being used, both at a private level and for commercial energy production. It has been found that large solar modules in particular are becoming increasingly significant. This is due to the fact that, when large solar modules are used, the costs with respect to assembly and cabling can be significantly reduced. However, it has also been found that the handling, in particular the assembly of such large solar modules, is relatively difficult. In particular, conventional assembly aids, such as, for example, an inherently stable frame being fitted, can be used less frequently with a large solar module since, on the one hand, they are more costly owing to the size of such solar modules and, on the other hand, they lead to problems such as, for example, occurrences of distortion and the like, which could lead to breakage of the solar module in the worst cases.

With the increasing use of large photovoltaic solar modules, which is a particularly recent development, new measures are therefore also required for fitting such solar modules to carrier structures on roofs or a substructure, which take into account the dimensions of such photovoltaic solar modules and the weight thereof.

The German utility model DE 94 017 41 U1 discloses a fixing structure for a solar module. Elongate fixing elements are fitted to the rear side of a frameless solar module and are provided with angled legs. There are formed in the legs holes, by means of which the solar module can be screwed to a carrier structure. It has been found that, with an arrangement of this type, precise tolerances must be complied with between the fixing elements and substructure. If these are not complied with, the solar module may be subject to incorrect alignment or occurrences of distortion which ultimately may lead to the breakage thereof. The German utility model DE 20 207 008 614 U1 discloses a carrier arrangement for solar modules which is particularly suitable for fitting the solar modules to a roof. At the rear side of the solar modules, single hooks and brackets are fitted, the hooks being hooked in tubular module carriers which are secured to the roof and the brackets ultimately being brought into engagement with corresponding module carriers. This arrangement leads to the individual solar modules being more heavily loaded locally at the fitting points of the hooks or brackets, which can again lead to occurrences of distortion which may ultimately result in a defect of the solar module.

Furthermore, the German utility model DE 20 2007 008 659 U1shows an arrangement in which frameless solar modules are provided with edge protection elements comprising resilient material and are then inserted into frame profile-members having engagement regions. Such solutions are suitable for small solar modules. However, the distortions which occur in the solar module during assembly with this system would lead to a high failure rate when they are used with large solar modules. With this solution, there are no support structures for the solar module, such as, for example, rear carriers.

The object of the invention is to provide a fixing structure for a large solar module which, with a simple and cost-effective construction, allows simple assembly avoiding the disadvantages described above with reference to the prior art.

### SUMMARY

This object is achieved with a fixing structure of the type mentioned in the introduction which has at least two receiving profile-members which can each be fixed to the other component from the solar module and substructure in a mutual relative position which corresponds to the relative position of the retaining profile-members, the retaining profile-member and the receiving profile-member having a mutually complementary profile shape so that the retaining profile-member can be received in a substantially positive-locking manner in the receiving profile-member, there being provided, on at least one pair comprising a mutually engaging retaining profile-member and receiving profile-member, mutually corresponding engagement formations, by means of which the retaining profile-member and the receiving profile-member engage with each other in a locking manner.

According to the invention, there are preferably arranged on the solar module elongate profile-members or individual profile-members, that is to say, either receiving profile-members or retaining profile-members, which extend over a large region in one direction of the solar module. These profile-members are then brought into positive-locking engagement with the corresponding other profile-member from the retaining profile-member and receiving profile-member. It is thereby ensured that the solar module is supported over a large region, that is to say, along the profile-members which are fitted directly thereto, and is also retained in a reliable manner, that is to say, by the said positive-locking. It may be advantageous in terms of assembly to incline the solar module and the profile-members which are directly connected thereto, as will be explained in greater detail below with reference to the individual developments of the inventions.

Furthermore, the mutually corresponding engagement formations ensure reliable mutual locking of the two profile-members so that the solar module is securely retained on the substructure. No additional fixing elements are thereby required, although these can still be fitted subsequently during assembly as security means, for example, as protection against theft. In principle, however, the notion according to the invention of two mutually engaging profile-members for fitting the large solar module to the substructure is suitable for adequate fixing and orientation of the solar module relative to the substructure, without additional elements which increase the complexity of assembly necessarily being required.

The term “solar module” in the context of the description of this invention is intended to include conventional photovoltaic solar modules for energy production. However, there are also included planar structures which use, for example, an interposed energy carrier, such as water.

In a development of the invention, there is provision for the retaining profile-member to have a portion which tapers preferably transversely relative to the longitudinal direction thereof and by means of which it can be inserted so as to be positioned in a corresponding widening portion of the retaining profile-member. The tapering portion and the corresponding widening portion bring about a positioning of the retaining profile-member and receiving profile-member which can be used to achieve a desired orientation of the solar module in a desired attitude. In this context, there is preferably provision for the retaining profile-member and the receiving profile-member each to be constructed in a trapezoidal manner at least in this portion. For instance, the retaining profile-member and the receiving profile-member may be trapezoidal over their entire profile depth or may only have a trapezoidal portion. As an alternative to a trapezoidal configuration, there may be provision for the retaining profile-member and the receiving profile-member each to be constructed as a circular profile-member in at least one portion.

In order to ensure mutual positive-locking of the receiving profile-member and the retaining profile-member, there is provision in a development of the invention for the receiving profile-member to have an undercut when viewed in a section orthogonal relative to the longitudinal direction and for the retaining profile-member to have a corresponding projection, the receiving profile-member being resiliently openable in such a manner that the retaining profile-member can be inserted in the receiving profile-member with resilient deformation, whereupon the projection and undercut engage one behind the other. It is thereby possible even during assembly to securely connect the receiving profile-member and retaining profile-member to each other in the manner of a locking connection so that a solar module which has been assembled can be removed from a substructure only with significant effort. This is particularly suitable for commercial solar parks, in which a plurality of solar modules are installed over a large surface-area, with the result that unintentional removal, for example, by means of theft, cannot be completely prevented or can be prevented only with high levels of monitoring. In such cases, disassembly of solar modules from the substructure is intended to be prevented or at least made considerably more difficult using structural means. In this context, there may be provision for the receiving profile-member to be able to be opened with an assembly tool. That is to say, it is not possible in this construction variant to open the receiving profile-member without the special assembly tool so that the removal of solar modules is made even more difficult.

With regard to the engagement formations, various solutions are provided according to the invention. According to one construction variant of the invention, there may be provision for the retaining profile-member to be provided with at least one bead and for the receiving profile-member to be provided with at least one correspondingly arranged complementary bead, which together form the engagement formation. Beads and complementary beads are thus formed locally on the retaining profile-members and the receiving profile-member. This can be carried out with a relatively low level of production complexity using conventional shaping techniques in the context of a sheet metal processing operation. For the stable construction of these beads or complementary beads, there may be provision for a plurality of directly adjacent beads and complementary beads to form the engagement formation, the beads and complementary beads each describing a section of a cone surface. Alternatively, however, they can also be produced in the form of sections of a cylinder surface. It should be noted that, in the region of the beads, according to the invention the profile-member material may also be partially broken. It is thus also possible to provide groups of several adjacent inclined beads. The beads, individually or in groups, may also be constructed in a wedge-like manner.

As an alternative to beads, in which the profile-member material is not broken or is only partially broken, there may further be provision for the retaining profile-member to be provided with recesses and flaps and for the receiving profile-member to be provided with correspondingly arranged complementary recesses and flaps which together form the engagement formation. That is to say, in this construction variant, the material of the retaining profile-members and the receiving profile-members is recessed locally over a relatively long, partially peripheral region and deformed by flaps being bent out. However, the flaps may also still be partially connected to the remaining profile-member material in the region bent from the profile-member and only partially separated therefrom.

In another alternative, there is provision for at least one component from the retaining profile-member and receiving profile-member to be provided with notches and for the other component from the retaining profile-member and receiving profile-member to be provided with correspondingly arranged receiving regions which are in particular indented or constructed as a recess and which together form the engagement formation. There may be provision for the notches to be constructed as hook-like, angular or spoon-like flaps, these notches engaging in or on the receiving regions. The receiving regions can be produced by means of correspondingly shaped recesses or by means of local material deformations. For easier assembly, there is provision in a development of the invention for the receiving regions to have a widened introduction portion for the notches and a fixing portion for securely retaining the notches.

The possibilities set out above for constructing the engagement formations all make provision for the retaining profile-members and receiving profile-members to mutually engage in a positive-locking manner on the one hand and to come into direct engagement with each other by means of beads, flap-like notches, bolts or the like on the other hand. This can be used to adjust a desired relative position of retaining profile-members and corresponding receiving profile-members relative to each other.

In this regard, there is provision in a development of the invention for the engagement formations, in particular the beads or flaps, to be at least partially inclined and/or to have a curved path relative to a longitudinal axis of the receiving profile-member and the retaining profile-member so that the degree of mutual engagement is increased as the mutual engagement continues. That is to say, the engagement formations form inclined tensioning faces which have the effect that, with continuing mutual engagement of the receiving profile-members and retaining profile-members following a relative movement, they are urged towards each other and are consequently mutually interlocked or wedged in addition to the positive-locking already mentioned above. This effect is increased in particular in that the path of the engagement formation is orientated in such an inclined manner that, when the solar module is assembled, the relative movement which brings about the tensioning effect is supported by the action of gravitational force. That is to say, the path of the engagement formations is determined in such a manner that the effect of the gravitational force of the solar modules which are arranged in an inclined manner provides a type of self-reinforcing effect and further increases the tensioning effect.

There have been described above in particular engagement formations in which the retaining profile-member and/or the receiving profile-member must be at least locally recessed, the surface thereof being “damaged”. As an alternative, there is provision in a development of the invention for the respective profile-members not to be damaged by means of cuts or punchings, but instead for engagement formations to be produced by shaping by means of local three-dimensional deformations of the surface. There may be provision for the retaining profile-member to be provided with local deformations and for the receiving profile-member to be provided with complementary or corresponding local deformations, the retaining profile-member in an assembly position being able to be inserted transversely relative to the longitudinal direction, with a region of the local deformations thereof which protrudes transversely relative to the longitudinal direction thereof, in a region of the receiving profile-member which is accordingly opened transversely relative to the longitudinal direction thereof and, after a relative displacement between the retaining profile-member and the receiving profile-member in the longitudinal direction thereof, the protruding region of the retaining profile-member engaging in a positive-locking manner behind a recessed region of the receiving profile-member which receives it. In this variant, there is preferably provision for the retaining profile-member and the receiving profile-member to be constructed as continuous profile-members in the region of the local deformations without interruption of the material. Consequently, it is possible for profile-members which are protected from corrosion, for example, by means of coating or electroplating, not to be subsequently damaged on the surface thereof and not to have their corrosion protection removed in an undesirable manner.

In this variant, in which the engagement formations are produced simply by means of shaping, a positive-locking assembly is achieved in accordance with a key/lock principle. This positive-locking mutual engagement of the receiving profile-member and retaining profile-member can be achieved simply by means of the shaping in the locally deformed regions. The fitting together in the context of the assembly is carried out by means of insertion transversely relative to the longitudinal direction of the profile-member and subsequent displacement in order to achieve the positive-locking in the longitudinal direction of the profile-member.

In a development of the invention, there is provision for ramp formations and/or stop elements to be provided on the retaining profile-member and/or on the receiving profile-member, which fix a predetermined positioning of the receiving profile-member and retaining profile-member relative to each other in the longitudinal direction of the profile-member or transversely relative to the longitudinal direction of the profile-member. Although a mutual alignment in a desired attitude is already produced owing to the positive-locking mutual engagement of the retaining profile-member and the receiving profile-member, such stop elements can determine a defined desired position in addition to this alignment effect, for example, by means of engagement in this desired position or the like. It is also thereby possible to prevent undesirable opening of the receiving profile-member.

As set out above, large regions of the solar module are supported by the receiving profile-member or retaining profile-member which is fitted thereto. The profile-member that is fitted directly to the solar module can accordingly be constructed so as to be weaker. In this regard, there may be provision for the component from the retaining profile-member and receiving profile-member that is fitted directly to the solar module to be constructed so as to be longer in the longitudinal direction of the profile-member than the other component. Furthermore, there may be provision for the component from the retaining profile-member and receiving profile-member that is fitted directly to the solar module to be constructed with a smaller depth when viewed in the direction orthogonal relative to the solar module than the other component. This has the advantage that a larger number of solar modules can be stacked for transport in a predetermined storage space. The deeper profile-members which are not fitted directly to the solar module can be stacked one inside the other in order to save space.

In order to fit retaining profile-members or receiving profile-members to the solar module, a heat-resistant adhesive layer can be provided. In a development of the invention, there is provision for the adhesive layer to have a minimum thickness of 2 mm and to be constructed in a resilient manner. Owing to the possibility of resilient deformation, the adhesive layer can compensate for production tolerances, assembly tolerances and different thermal expansions in the application case. As adhesive it is possible to use, for example, heat-resistant silicone masses.

It should also be added that, as an alternative to beads or flaps, there may further be provision for at least one component from the retaining profile-member and receiving profile-member to be provided with bolts, in particular head bolts, and for the other component from the retaining profile-member and receiving profile-member to be provided with correspondingly arranged receiving regions which together form the engagement formation. In order to achieve the tensioning effect described above, there may be provision in this regard for the receiving regions to have an inclined path.

It has further been found that, when the connection between the retaining profile-member and receiving profile-member is produced, it may be advantageous with respect to the production tolerances for the receiving profile-member to be pre-assembled with a degree of movement clearance on the sub-construction prior to the connection to the receiving profile-member being brought about. This movement clearance can be produced, for example, by the receiving profile-member being inserted into the corresponding fixing holes of the sub-construction with screws which are securely connected thereto and the fixing nuts not yet being screwed, or at least not yet securely screwed, to the screws. The movement clearance of the receiving rail is then defined by the shape and size of the fixing holes in the sub-construction. The movement clearance should not be so large that the retaining profile-member and receiving profile-member no longer fit together correctly. Since the production tolerances are intended to be compensated for by the movement clearance, the optimum movement clearance is in the range of the maximum production distribution to be compensated for. After the retaining profile-member has been introduced into the receiving profile-member and a positive-locking connection has been produced between the retaining profile-member and the receiving profile-member, the movement clearance between the sub-construction and the receiving profile-member can be limited or completely eradicated, for example, by tightening the above-mentioned screw/nut connection.

As already set out above, there may be provision according to the invention for each retaining profile-member and receiving profile-member to be inclined relative to the horizontal. Depending on the location at which the solar module is positioned with the fixing structure according to the invention, a greater or lesser degree of inclination may be selected. Conventionally, solar modules in the vicinity of the equator are arranged in a more planar manner or with no inclination at all relative to the horizontal, whereas, in installation locations which are further away from the equator, the inclination is increased for the purposes of adequate solar exposure.

In the context of the description of the invention, it has already been explained that either elongate rail-like retaining profile-members or individual retaining profile-member elements can be arranged at the rear side of the solar module. In the latter case, there may be provision according to the invention for a plurality of retaining profile-member elements to be aligned in a linear manner relative to each other at the rear side of the solar module or to be fitted to a common retaining profile-member rail. With regard to the specific construction of an individual retaining profile-member element, there may be provision for it to have a head-like projection which extends away from the solar module and which can be received with an undercut in a complementary receiving profile-member. The head-like projection may be constructed so as to be rotationally symmetrical or so as to extend transversely relative to the direction of the projection.

In order to permanently ensure in relation to the solar module a predetermined relative position of the retaining profile-members which are fitted to the rear of the solar module, a development of the invention provides for at least one gripping flap for engagement with a front side of a solar module. Preferably, there is provision for the at least one gripping flap to be arranged on the retaining profile-member. That is to say, the respective retaining profile-member engages around the solar module locally with the gripping flap in the manner of a corner and thus ensures a predetermined orientation. This may also be advantageous, for example, when the retaining profile-members are fitted to the rear side of the solar module with an adhesive layer since the retaining profile-member thus remains in a predetermined orientation with respect to the solar module when the adhesive has not yet dried. It is also thereby possible to prevent undesirable sliding or creeping “migration” of the solar module when the adhesive layer fails, for example, owing to thermal impairment of the adhesive.

In this regard, there is provision in one configuration of the invention for the at least one gripping flap to extend from a portion of the retaining profile-member that is fitted to the rear side of the solar module as far as the front side and to extend partially around it. A plurality of gripping flaps may also be provided for each retaining profile-member.

As an alternative to fitting the at least one gripping flap to the retaining profile-member in this manner, there may further be provision according to the invention for the at least one gripping flap to extend from a portion of the retaining profile-member arranged so as to be remote from the rear side of the solar module as far as the front side and to extend partially around it.

It has been set out above that the fixing structure according to the invention is distinguished in that the receiving profile-member and the retaining profile-member mutually engage in the longitudinal direction thereof over a large region and thus ensure secure retention of the solar module. This can be achieved by means of planar positive-locking or by means of local engagement at a plurality of locations. In a development of the invention, there is provision for there to be provided on the retaining profile-member or/and on the receiving profile-member local projections which provide a minimum spacing between the retaining profile-member and receiving profile-member. This minimum spacing is a small gap which is just large enough to allow air to circulate and water to flow away. Long-term corrosion effects can thereby be prevented. Such local projections may be provided in greater or smaller numbers in the longitudinal direction of the profile-members. The abutment of the receiving profile-member and retaining profile-member in the region of these local projections should be planar for stabilisation. In particular, the abutment face may be constructed in the manner of a plateau or ring. In this regard, there is provision in a development of the invention for the local projections to be provided at the centre thereof with a recess or indentation, an abutment between the local projection and the portion of the retaining profile-member or receiving profile-member which engages therewith being produced in an annular edge region of the local projection which surrounds the recess. That is to say, the local projections are located not punctually but instead over a closed annular face at the face of the other profile-member facing the projections. The recesses promote the circulation of air and the discharge of water.

In order also to produce a safe electrical connection when a solar module is assembled with a fixing structure according to the invention, there may also be provision in the fixing structure according to the invention for an electrical connector to be fitted in each case to the retaining profile-member and for a complementary electrical connector to be fitted to the receiving profile-member, the electrical connector and the complementary electrical connector being in a contacting state of engagement when the receiving profile-member and the retaining profile-member are in mutual engagement in a locking manner.

The invention further relates to a retaining profile-member for a fixing structure of the above-described type, having the features described above for the individual retaining profile-members.

The invention further relates to a receiving profile-member for a fixing structure of the type described above, having the features specific to the receiving profile-member set out above. Finally, the invention also relates to a substructure having a retaining profile-member or a receiving profile-member of the above-described type.

The invention further relates to a solar module, in particular a large solar module, having a fixing structure of the type described above.

### BRIEF DESCRIPTION OF THE DRAWINGS

The invention is explained below by way of example with reference to the appended Figures, in which:

FIG. 1 is an explanatory overview of a solar module with substructure;

FIG. 2 is a front view of the solar module with a retaining profile-member;

FIG. 3 is a modified front view of the solar module with a retaining profile-member;

FIG. 4 is another modified schematic view of the solar module with a retaining profile-member;

FIGS. 5a to 5c are schematic illustrations of various assembly phases with a solar module according to FIG. 4;

FIGS. 6a to 6c are views according to FIGS. 5a to 5c with an assembly tool;

FIG. 7 is a view according to FIG. 1 to explain the invention;

FIG. 8 is a schematic illustration of an alternative profile-member;

FIG. 9 is an alternative to FIG. 8;

FIG. 10 is another alternative to FIGS. 8 and 9;

FIG. 11 is a schematic illustration of another embodiment of the invention;

FIGS. 12a and 12b are front views of the profile-member of the embodiment according to FIG. 11;

FIG. 13 is a schematic illustration of another embodiment of the invention;

FIGS. 14a and 14b are front views of the profile-member of the embodiment according to FIG. 11;

FIG. 15 is a perspective view of another embodiment of the invention;

FIG. 16 is a perspective view of another embodiment of the invention;

FIG. 17a is a perspective view of two profile-members of another embodiment of the invention;

FIG. 17b is a front view of the profile-members according to FIG. 17a;

FIG. 17c is a view according to FIG. 17a, but in the assembled state;

FIG. 17d is a view according to FIG. 17b, but in the assembled state;

FIG. 18a is a perspective view of another embodiment of the invention;

FIG. 18b is a front view of the configuration according to FIG. 18a;

FIGS. 19a to 19d illustrate various states during the assembly of another configuration of the invention;

FIGS. 20a to 20c are perspective views of the assembly of the configuration according to FIGS. 19a to 19d;

FIG. 21 is another configuration of the invention;

FIG. 22 is another configuration of the invention;

FIG. 23 is another configuration of the invention;

FIG. 24 is another configuration of the invention;

FIG. 25 is a view similar to FIG. 7 with another configuration of the invention;

FIG. 26a is a retaining profile-member of another configuration of the invention;

FIG. 26b is a lateral view of a receiving profile-member for the retaining profile-member according to FIG. 26a;

FIGS. 27a, b, c illustrate various phases during the assembly of a retaining profile-member with a receiving profile-member having anti-theft protection;

FIG. 28 is another configuration of the invention;

FIGS. 29a, b, c illustrate various deformation situations for the embodiment according to FIG. 28;

FIGS. 30a, b are views relating to space-saving transport for solar modules having a fixing structure in accordance with the embodiment according to FIG. 28;

FIGS. 31a, b, c illustrate various assembly situations of solar modules according to the invention when fitted to a roof;

FIG. 32 is another embodiment according to the invention of a solar module having a fixing structure;

FIG. 33 is an enlarged perspective view of a fixing element of the configuration according to FIG. 32;

FIG. 34 illustrates another configuration of the invention with a corresponding solar module;

FIG. 35 is an enlarged perspective view of a fixing element according to FIG. 34;

FIG. 36 illustrates the co-operation of the receiving profile-member and retaining profile-member with respect to the construction variant according to FIG. 34;

FIG. 37a illustrates another configuration of the invention prior to assembly;

FIG. 37b illustrates the configuration according to FIG. 37a in the assembled state;

FIG. 38 is an axially orthogonal sectioned view in the region of the mutually engaging receiving profile-member and retaining profile-member;

FIG. 39 is an alternative to the configuration according to FIG. 34;

FIG. 40 is an enlarged perspective view according to FIG. 35 of an alternative configuration of a fixing element according to the present invention;

FIG. 41 is a corner region of a receiving profile-member with local projections;

FIG. 42 is a perspective view with transparently drawn solar modules relating to a development of the retaining profile-member;

FIG. 43 is an alternative embodiment to the configuration according to FIG. 42;

FIG. 44 is an alternative embodiment to the configuration according to FIGS. 42 and 43;

FIG. 45 is a detailed view of a component of an engagement formation according to the invention;

FIG. 45a is a detailed view of an opening in the other component which cooperates with the engagement formation according to FIG. 45;

FIG. 46 illustrates another configuration of the invention prior to the assembly;

FIG. 46a is a detailed view of the engagement formation of the configuration according to FIG. 46, arranged on the retaining profile-member;

FIG. 46b is a detailed view of the engagement formation of the configuration according to FIG. 46, arranged on the receiving profile-member;

FIG. 47 illustrates the configuration of the invention illustrated in FIG. 46 after assembly;

FIG. 48a is a receiving profile-member according to a development of the present invention for fitting to the rear side of a solar module;

FIG. 48b is an axially orthogonal section of an alternative configuration of the receiving profile-member with respect to FIG. 48a;

FIG. 49 is a retaining profile-member which can be made to co-operate with the receiving profile-member according to FIG. 48a; and

FIG. 50 shows a mounted state with a receiving profile-member according to FIG. 48 and a retaining profile-member according to FIG. 49.

### DETAILED DESCRIPTION

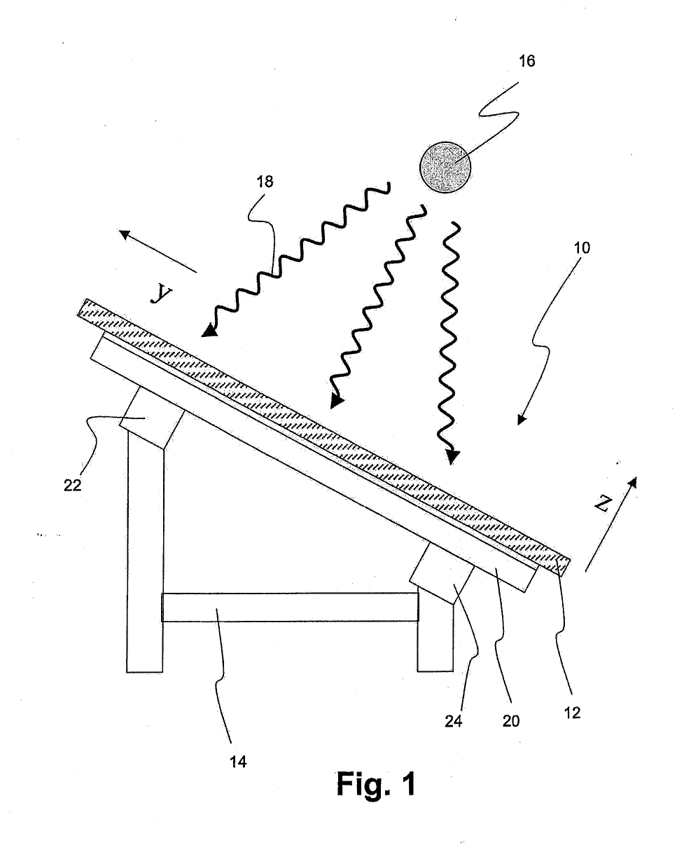

FIG. 1 illustrates an arrangement 10 for a solar module as generally used, for example, in photovoltaic solar power stations. It can be seen that a solar module 12 is arranged on a substructure 14. The solar module 14 is irradiated with UV rays 18 by the sun 16. The solar module 12 converts the UV radiation photovoltaically into electrical current as known per se. The invention substantially relates to the fixing structure for the solar module 12.

The solar module 12 is constructed so as to have no frame and to be relatively large, for example, with dimensions of 2.6 m×2.2 m. Such large solar modules must be supported at the rear side thereof. To this end, longitudinal profile-members 20 are fitted to the solar module 12. The longitudinal profile-members 20 are fixed with regular spacing relative to each other to the rear side of the solar module 12 and extend substantially parallel with each other in the Y direction. In the X direction orthogonal relative to the plane of the drawing, transverse carriers 22, 24 extend and are provided to fit the solar module 12 to the substructure 14.

There are various requirements for fixing the solar modules 12 to the substructure. It is thus necessary for the solar modules to be supported on the substructure 14 in a substantially tension-free manner. Furthermore, the solar modules 12 should be able to be mounted in a simple manner and where possible should be able to be permanently fixed to the substructure 14 without any or with only a small number of additional fixing means. This is the objective of the invention.

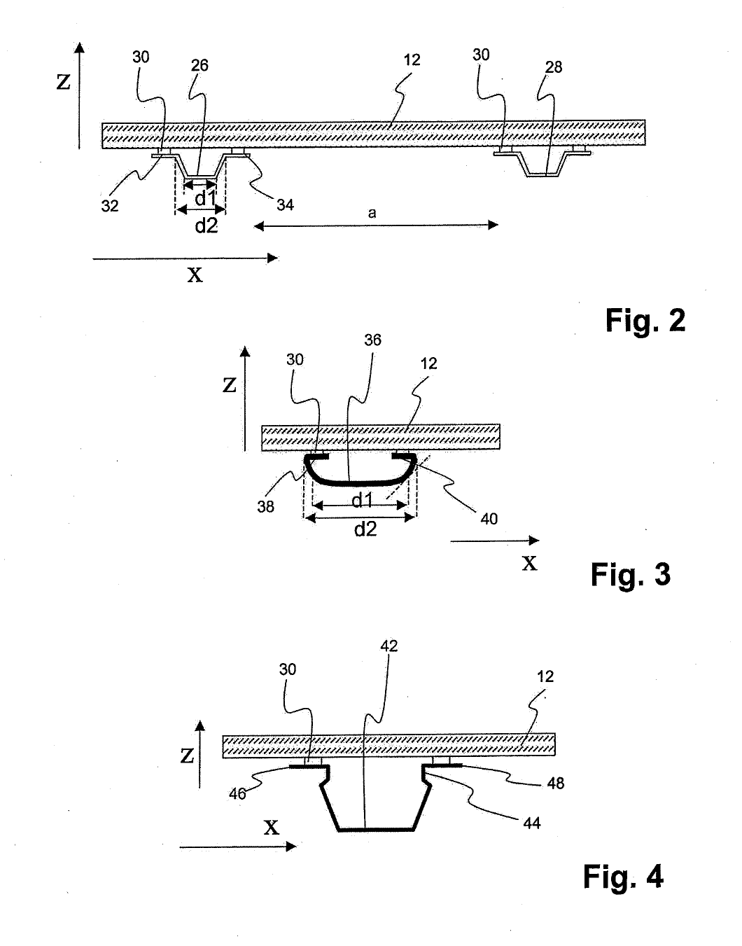

FIG. 2 illustrates a configuration of the solar module 12 according to the invention, only a portion of this solar module 12 being illustrated in the X-direction. It can be seen that, at the lower side of the solar module 12, trapezoidal profile-members 26, 28 are fitted. These are connected to the lower side of the solar module 12 with layers 30 of adhesive which are several millimetres thick. If the profile-members 26 and 28 are considered in greater detail, it can be seen that, in their narrowest region, they have a width d1 and, in a transition region to lateral wings 32, 34, have a larger width d2. Depending on the size of the solar module 10, a plurality of such profile-members are fitted to the lower side thereof, preferably with a spacing a of 60 cm. However, larger or smaller spacings can also be selected.

The profile-members 26 and 28 are referred to below as retaining profile-members since they are provided for retaining the solar module 10.

FIG. 3 illustrates another configuration of such a solar module 12. A rounded hollow profile-member 36 is provided thereon, again by means of adhesive layers 30. It can be seen that the hollow profile-member 36 has two widths, that is to say, in the narrowest region thereof, the width d1, and, in the widest region thereof, the width d2. The two wings 38 and 40 are curved inwards. The profile-member 36 also acts as a retaining profile-member, as will be set out in detail below.

FIG. 4 illustrates another configuration of the invention, having another profile shape which differs from FIGS. 2 and 3. A plurality of retaining profile-members 42 are again fitted to the solar module 12 by means of adhesive layers 30 which are several millimetres thick. The retaining profile-member 42 is constructed in a trapezoidal manner in the lower region thereof in a similar manner to the retaining profile-member 26. However, it has at both sides thereof a recessed region 44 which forms an undercut. From this recessed region 44 in turn extend the two wings 46 and 48, by means of which the retaining profile-member 42 is fitted to the solar module 10.

In all three of FIGS. 2 to 4, it is possible to see the orientation with reference to the X and Z axes which have been drawn. Furthermore, for all three configurations, it should additionally be noted that the layer 30 of adhesive 30 is in each case resilient and can thus ensure slight compensation of the relative position between the respective retaining profile-member and the solar module 12 and compensation for different thermal expansions owing to the differing materials of the retaining profile-member 42 and the solar module 12.

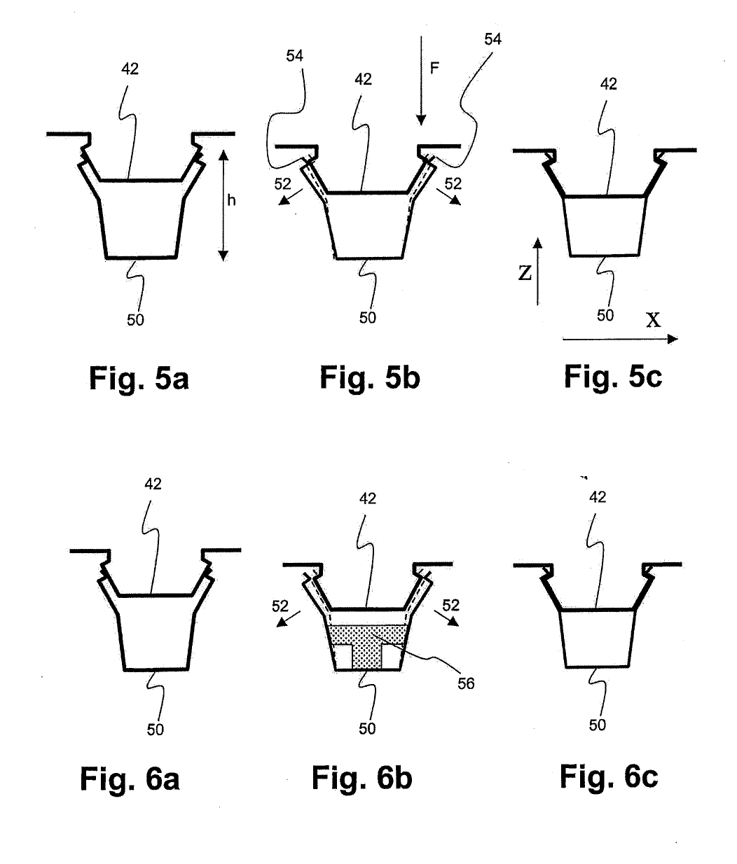

Based on the configuration according to FIG. 4, and with reference to the illustration according to FIGS. 5a to 5c, it can be seen that the retaining profile-member 42 which is fitted to the solar module not illustrated in FIGS. 5a to 5c can be inserted into a corresponding receiving profile-member 50. The receiving profile-member 50 has a substantially corresponding profile shape, but extends over a greater height h than the retaining profile-member 42, whereby the torsional rigidity and flexural strength thereof orthogonally relative to the longitudinal axis thereof are increased. The receiving profile-member 50 is, as explained in detail below, connected to the substructure.

In the state according to FIG. 5a, the retaining profile-member 42 is just resting on the receiving profile-member 50. By being acted on with a joining force F which may correspond, for example, substantially to the force of gravity acting on the solar module, the receiving profile-member 50 is resiliently opened in accordance with the arrows 52. The initial state is indicated in FIG. 5b with broken lines, the opened state in contrast being illustrated with a solid line. In order to facilitate the introduction, the receiving profile-member 50 has, at the free ends thereof, folded inclined introduction faces 54.

Finally, the retaining profile-member 42 is pushed so far into the receiving profile-member 50 that the folded inclined introduction faces 54 can engage in the region 44 and consequently engage around the retaining profile-member 42 in a positive-locking manner. In this state, the retaining profile-member 42 is retained by the receiving profile-member 50 in a positive-locking manner. It is supported on the receiving profile-member 50 both laterally in the X direction and in the Z direction. There is produced a reliable retention function between the receiving profile-member 50 and retaining profile-member 42 and consequently also between the substructure which is connected to the receiving profile-member 50 and the solar module which is connected to the retaining profile-member 42. The connection is simple to produce, is subject to no or only small stresses which are transmitted to the solar module and compensates for tolerances. Furthermore, the positive-locking results in the solar module being positioned relative to the substructure in a desired position.

FIGS. 6a to 6c illustrate an assembly operation which is comparable with FIGS. 5a to 5c. However, the only difference is that, in the step 6b, the receiving profile-member 50 is opened with an additional assembly tool 56 and the resilient deformation according to the arrows 52 does not have to be undertaken by pressing in the retaining profile-member 42, but instead the receiving profile-member 50 is already “pre-opened”.

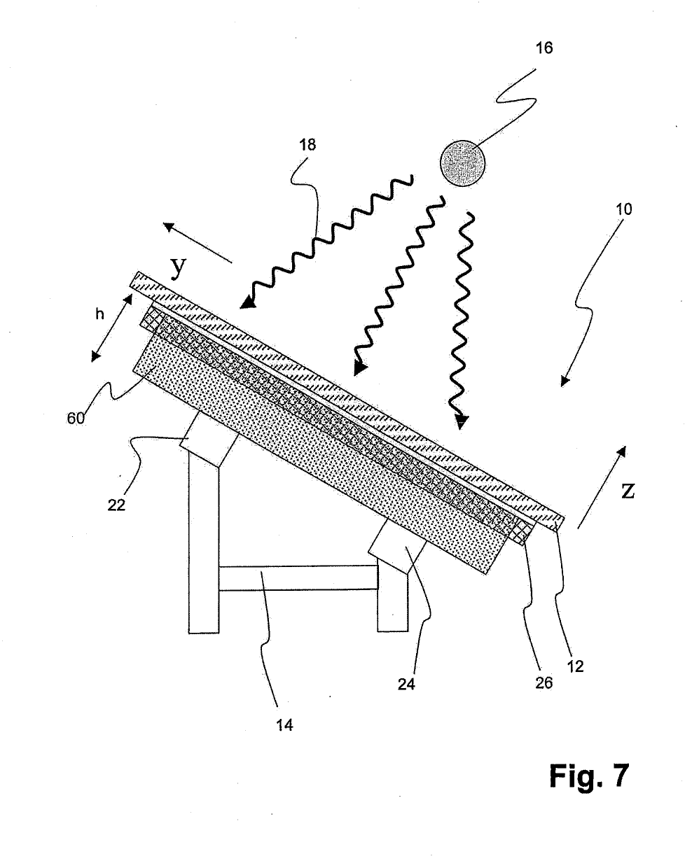

FIG. 7 illustrates the structure according to the invention based on the illustration according to FIG. 1, a retaining profile-member, for example, the trapezoidal retaining profile-member 26 according to FIG. 2, being fitted to the solar module 12 by means of the layer of adhesive. The retaining profile-member 26 is received in a corresponding trapezoidal receiving profile-member 60 with a relatively large height h. The receiving profile-member 60 is connected to the transverse carriers 22 and 24, for example, by means of screwing.

With the structure illustrated in FIG. 7, a large solar module 12 can also readily be fitted to the substructure 14. Occurrences of distortion, which may be brought about with conventional solutions owing to the screwing, are not brought about with this structure. If necessary, the retaining profile-members 60 can be fitted to the transverse carriers 22, 24 with a degree of clearance in the X direction (in FIG. 7 orthogonal relative to the plane of the drawing), in order to allow compensation for tolerances. When produced with the conventional degree of precision, however, the tolerance compensation which is obtained by the resilience of the adhesive layer 30 is sufficient.

With reference to FIG. 7, it should be noted that the length of the receiving profile-member 60 along the longitudinal axis of the profile-member can be selected to be shorter, sometimes even considerably shorter, than the length of the retaining profile-member 26. This is due to the fact that the retaining profile-member 26 is intended to support the solar module 12 over a large region in the Y direction. The receiving profile-member 60 is intended in contrast to provide sufficient retention for the retaining profile-member 26 on the substructure 14 and can additionally provide a surface supporting effect. Furthermore, it should be noted that the retaining profile-member 26 and the receiving profile-member 60 complement each other. The retaining profile-member 26 supports a large region of the solar module 12. The flexural strength is, however, achieved substantially by means of the significantly deeper receiving profile-member 60. The length and height/depth thereof can be adapted to the specific application (loading by snow, wind, etcetera). The division between the relatively flat retaining profile-member 26 and relatively deep receiving profile-member 60 whose dimensions are selected as required, has the advantage that solar modules 12 which are provided with retaining profile-members 26 can be stacked in a space-saving manner and thus transported. The deep receiving profile-members can be inserted one inside the other and thus stacked for transport. They can thus also be transported in a space-saving manner. Furthermore, standardised solar modules can be used with one and the same retaining profile-members 26 and only the receiving profile-members 60 can be adapted as required to the loads which are to be anticipated.

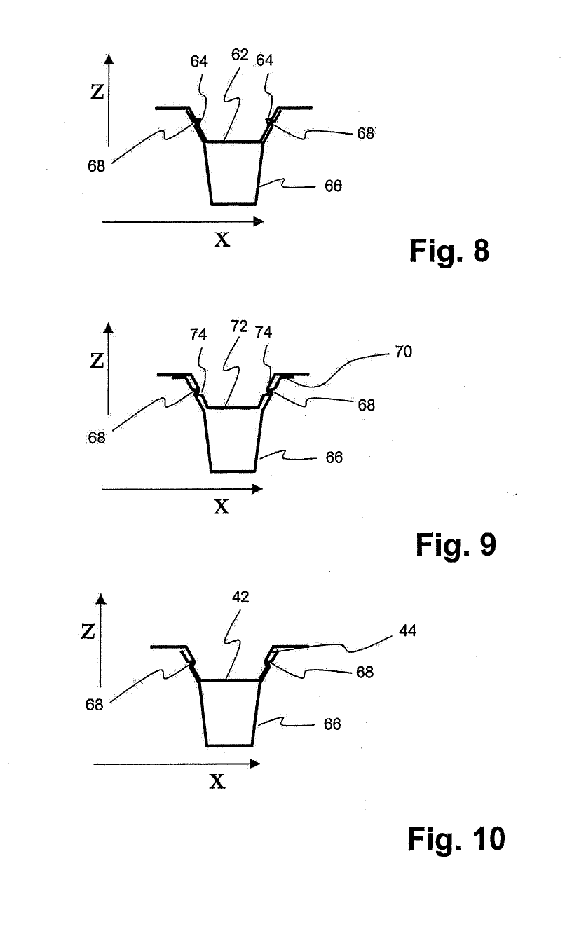

With reference to FIGS. 8 to 21, 22, 26a and 26b, details will be set out below relating to various embodiments and configurations of receiving profile-members and retaining profile-members and the effects resulting therefrom.

It should be noted that the following description is not a definitive listing of receiving profile-members and retaining profile-members according to the invention but instead illustrates advantageous embodiments which can also be modified or combined with each other by the person skilled in the art as necessary, whilst still being included within the scope of protection of the patent claims. All of these profile-members are provided for being fixed to the solar module in a manner described per se above, for example, by means of adhesive-bonding, and fitted to the substructure, with or without tolerance compensation.

FIG. 8 illustrates a retaining profile-member 62 which has a trapezoidal basic shape. In the region of the inclined trapezoidal faces, there are provided kinks or beads 64 which extend along the longitudinal axis of the profile-member (parallel with the Y axis) in the longitudinal direction and which are produced by means of shaping. They may extend parallel with or in an inclined manner relative to the longitudinal axis of the profile-member, in order to achieve the tensioning effect which will be explained in detail below.

FIG. 8 illustrates a corresponding receiving profile-member 66 which opens in an upward direction. At the inclined faces corresponding to the inclined trapezoidal faces, there are provided kinks 68 which are produced by means of shaping and which, in the assembled position illustrated in FIG. 8, engage in the kink 64. The assembly is carried out as explained with reference to FIGS. 5a to 5c and 6a to 6c, respectively.

FIG. 9 illustrates an embodiment which is modified compared with FIG. 8. The receiving profile-member 66 remains substantially unchanged with respect to the receiving profile-member 66 of FIG. 8. Only at the free upper end regions are there provided wing portions 70 on which a modified retaining profile-member 72 rests. The retaining profile-member 72 is again trapezoidal and has, at the inclined trapezoidal faces thereof, kink portions 74 which protrude outwards. With these, it is in engagement with the kink portions 68 of the receiving profile-member 66. The assembly is carried out as explained with reference to FIGS. 5a to 5c and 6a to 6c, respectively.

The configuration according to FIG. 10 is a combination of a receiving profile-member 66, as illustrated in FIG. 8, with the portions 68 already described which are produced by means of shaping and which protrude inwards. A retaining profile-member 42 is inserted into this receiving profile-member 66 and substantially corresponds, in terms of its basic configuration, to the retaining profile-member 42 according to FIG. 4. The folded portions 68 of the receiving profile-member 66 engage in the undercuts 44 on the retaining profile-member 42.

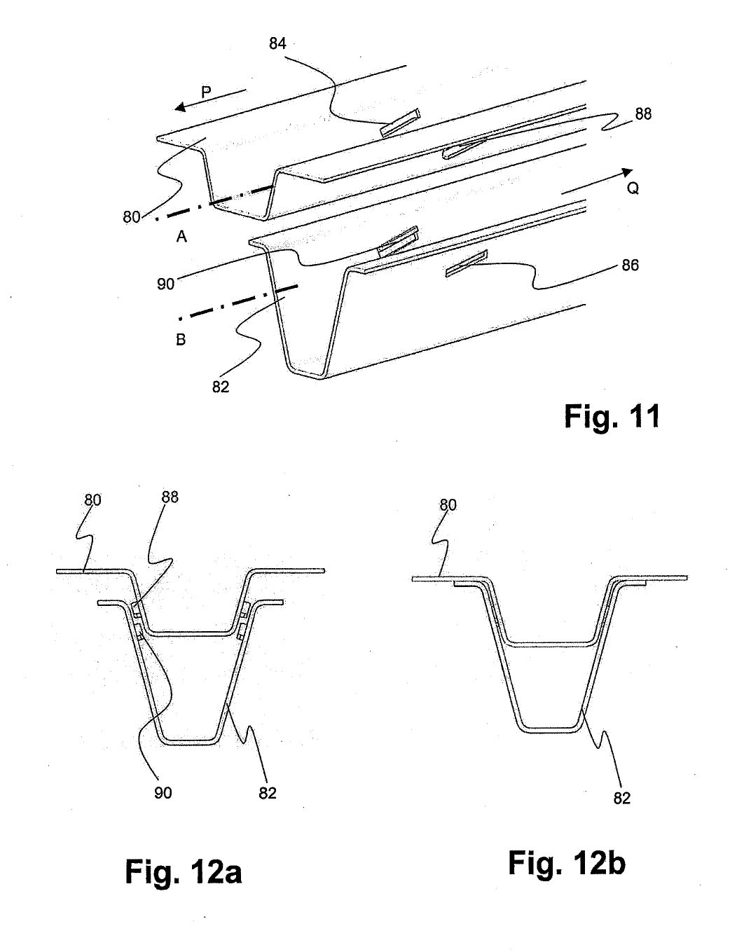

FIGS. 11, 12a and 12b illustrate another embodiment of the invention. A retaining profile-member 80 and a receiving profile-member 82 can be seen in FIG. 11. Both the retaining profile-member and the receiving profile-member have recessed regions 84, 86 from which flaps 88, 90 are bent. It can be seen that the recessed regions 84, 86 and the flaps 88, 90 which are bent therefrom extend not in a parallel manner but instead inclined relative to the direction of a respective longitudinal axis A or B of the profile-member. It can also be seen that, with the receiving profile-member 82, the flaps 90 are bent in an inward profile direction, but with the retaining profile-member 80 the flaps 88 are bent in an outward profile direction. As shown in FIG. 12a, this results, when the retaining profile-member 80 is inserted into the receiving profile-member 82, in the flaps 88 and 90 being caused to co-operate with and ultimately slide on each other.

During the assembly, the retaining profile-member 80 is inserted into the receiving profile-member 82 in such a manner that the flaps 88 engage behind the flaps 90 and vice-versa so that the flaps 88 reach the recessed regions 86 of the receiving profile-member, the flaps 90 of the receiving profile-member at the same time reaching the recessed regions 84 of the retaining profile-member.

If a relative movement simultaneously occurs when the two profile-members 80 and 82 are joined together, as indicated by the arrows P and Q, for example, in such a manner that—as illustrated in FIG. 7—the solar module is fitted to the substructure in an inclined manner relative to the horizontal and, owing to its gravitational force, is moved in accordance with the arrow P relative to the receiving profile-member 82, the individual flaps 88 and 90 slide on each other and act as wedges or inclined tensioning faces so that both profile-members 80 and 82 are drawn towards each other and wedged together owing to the wedge effect. Finally, the state is reached, as illustrated in FIG. 12b, in which the two profile-members 80 and 82 are fixedly joined to each other and, owing to the mutually engaging flaps 88 and 90 and receiving regions 84 and 86, can be separated from each other only with the application of considerable force.

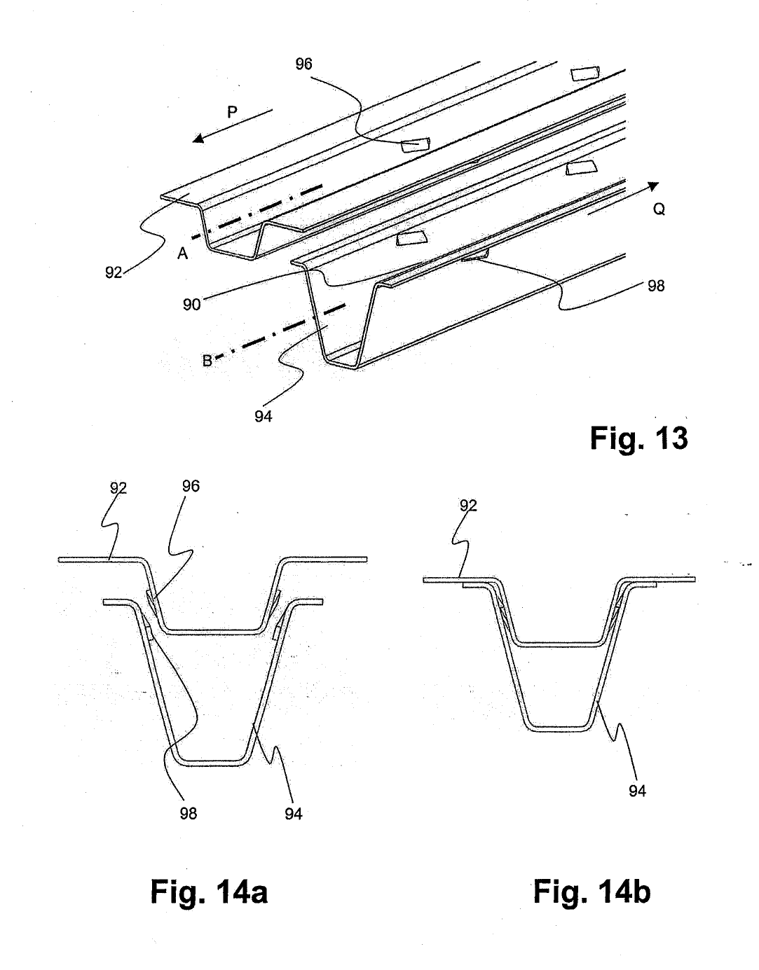

FIGS. 13, 14a and 14b illustrate a similar solution, as described with reference to FIGS. 11, 12a and 12b, the flaps only being bent slightly from the profile-members. A retaining profile-member 92 and a receiving profile-member 94 can be seen which are constructed with flaps 96 and 98, respectively. The method of operation is in principle the same as that described in detail with reference to FIGS. 11, 12a and 12b.

It should be noted that the flaps 96 and 98 can also be replaced purely by beads without damaging the profile-member material, that is to say, purely stamped portions, which co-operate in the same manner as the flaps and recesses described above. Again, the path of the flaps 96, 98 or stamped portions is inclined relative to the longitudinal axis A and B of the profile-member, respectively so that, during assembly, for example, as a result of gravitational force, the mutual tensioning effect of the two profile-members described above is achieved.

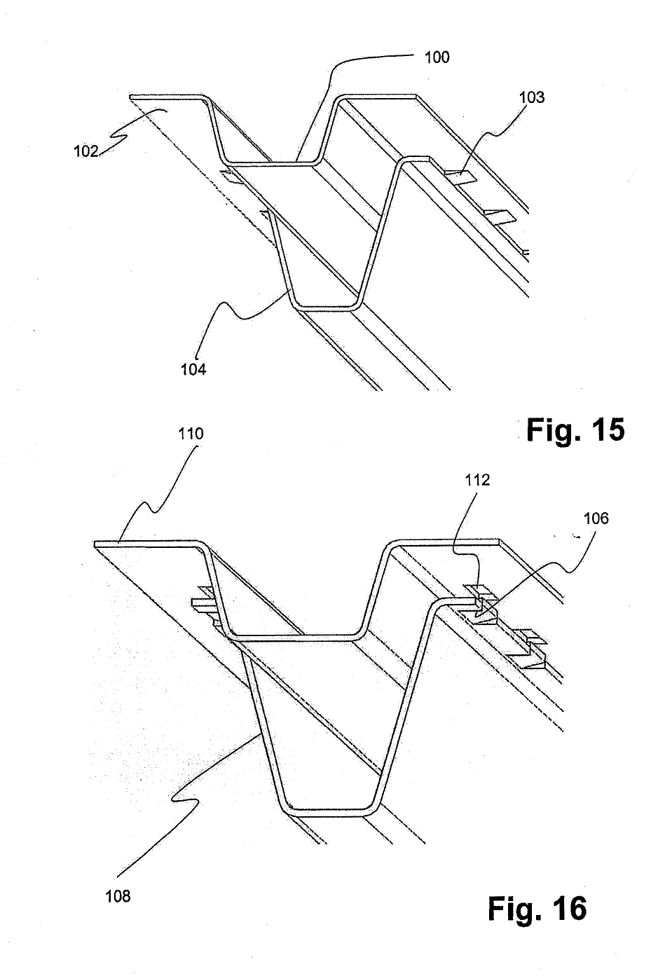

FIG. 15 illustrates another configuration of the invention. In this configuration, flaps are slightly bent from the profile plane on a trapezoidal retaining profile-member 100 in the region of the wing 102 thereof and engage on the lateral edge of a receiving profile-member 104. Undesirable opening effects can thereby be prevented. Such flaps can also be used with profile-members as described above with reference to FIGS. 8 to 14.

FIG. 16 illustrates an alternative to the configuration according to FIG. 15. In this configuration, undesirable occurrences of opening are prevented by flaps 106 which are provided on the lateral portion of a receiving profile-member 108 and which engage in corresponding recesses 112 during assembly with a retaining profile-member 110.

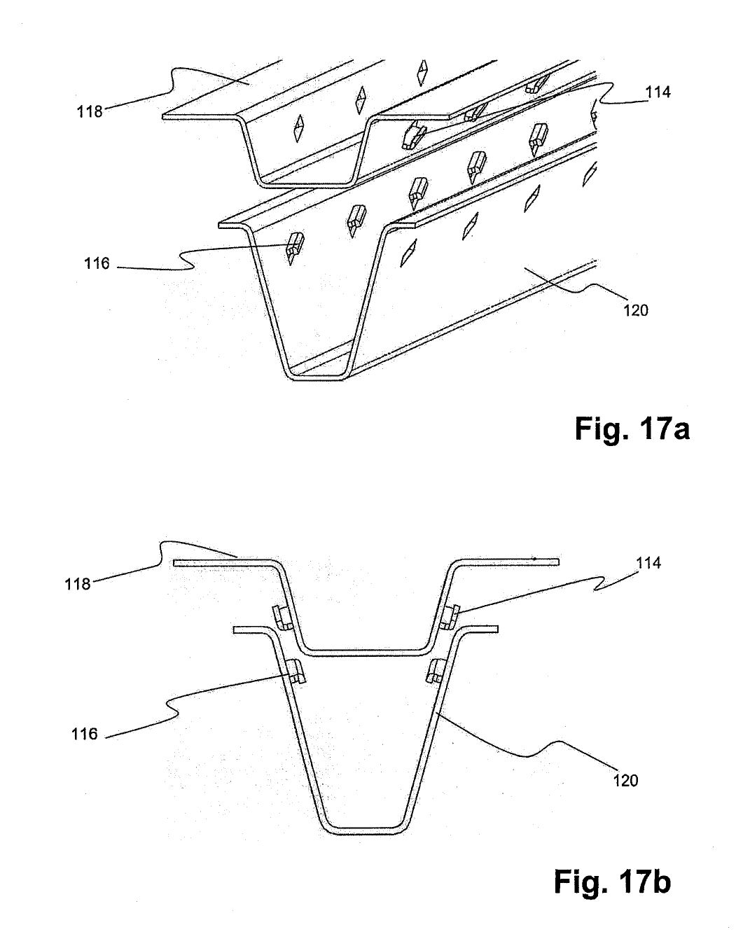

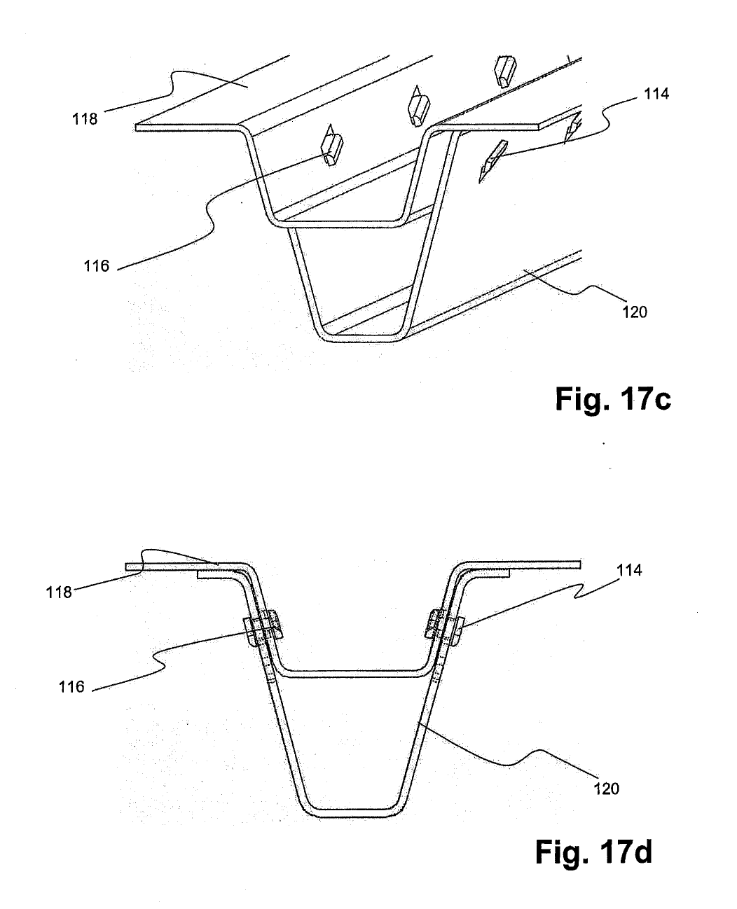

FIGS. 17a to 17d illustrate a development of the configurations according to FIGS. 11, 12a and 12b. Flaps 114 and 116 of the retaining profile-member 118 and receiving profile-member 120 formed by means of cutting and bending are constructed in a hook-like manner, as can also be seen clearly in FIG. 17b. In FIGS. 17c and 17d, it can be seen that these hook-like flaps then engage in the recesses and almost surround them so that the mutual retention of the receiving profile-member and retaining profile-member can be further increased. Again, the flaps extend in an inclined manner relative to the longitudinal axis of the profile-member in order to achieve the above-described tensioning effect.

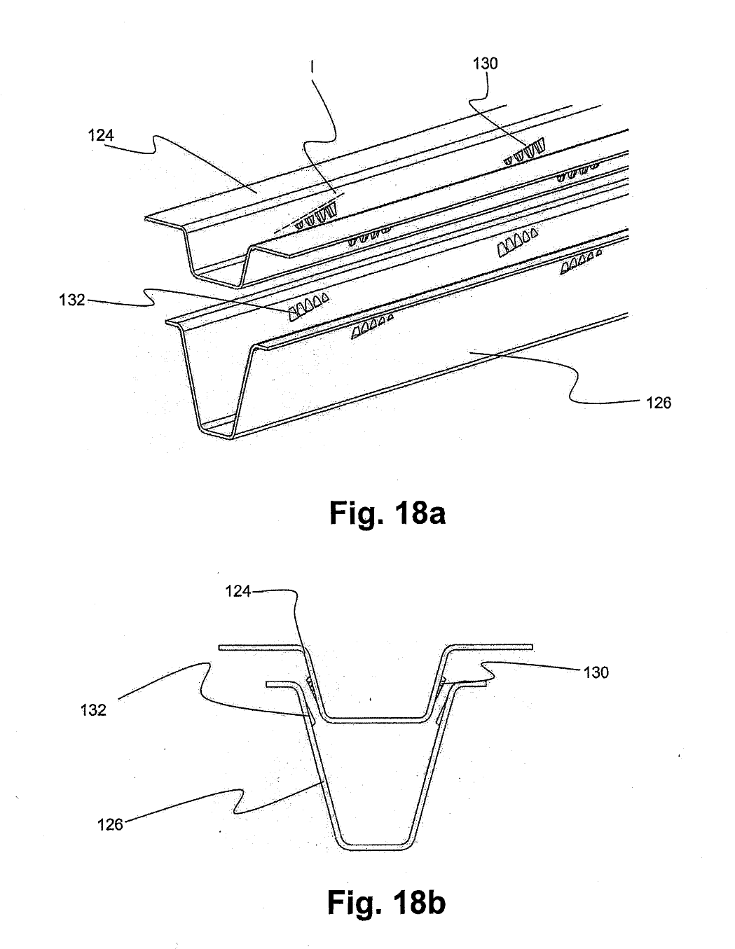

FIGS. 18a and 18b illustrate another configuration of the invention in which rows of beads 130 and 132 are arranged on the retaining profile-member 124 and the receiving profile-member 126, respectively. These are local deformations which extend outwards from the retaining profile-member 124 and inwards from the receiving profile-member 126. The individual beads are substantially in the form of a sphere portion, each row 130, 132 of beads terminating on a notional line I which is indicated in FIG. 18a as a broken line. Abutment regions are thereby produced, that is to say, along the defined lines I of the respective rows 130 and 132 of beads, which, in the same manner as described with reference to FIG. 11 or 13, can be brought into engagement with each other.

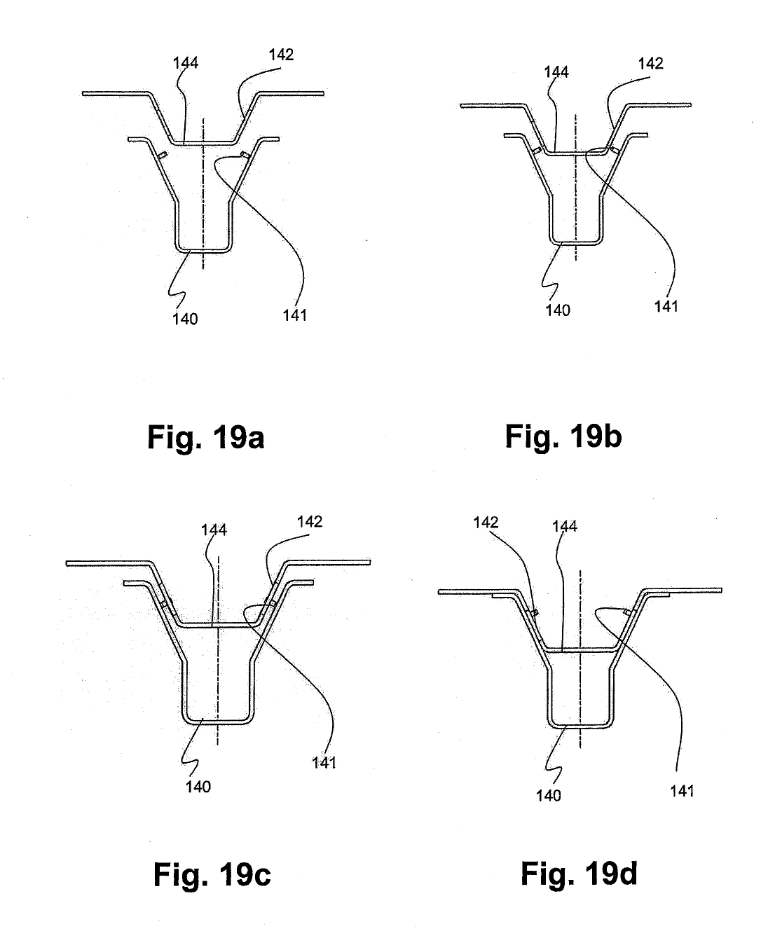

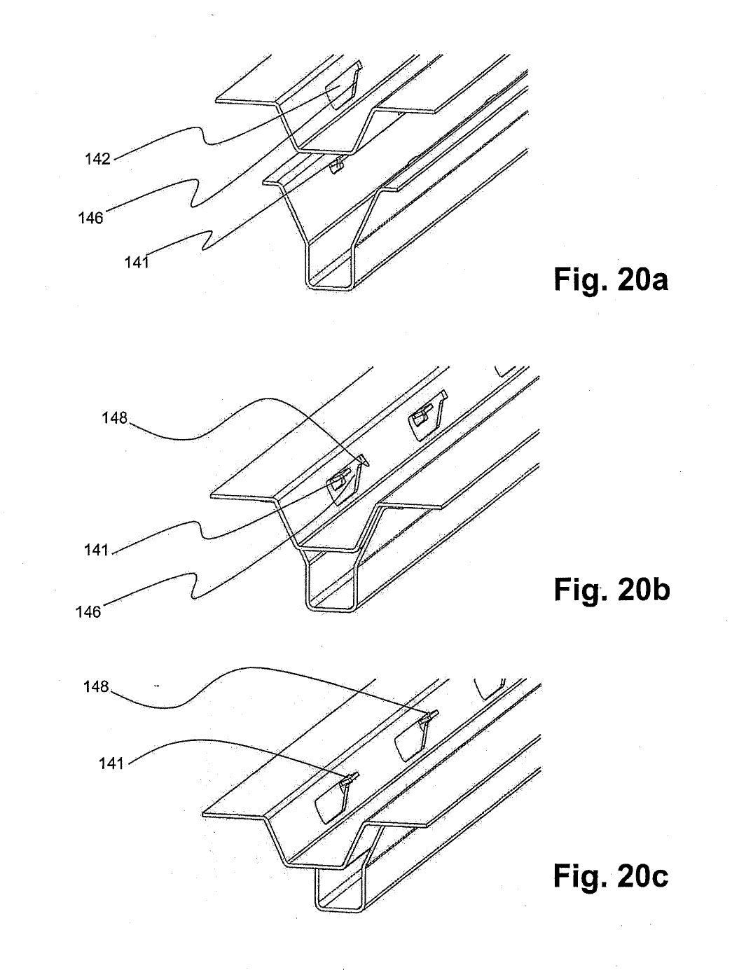

FIGS. 19a to 19d illustrate another configuration of the invention in various phases during assembly. In this configuration, inwardly bent flaps 141 are provided on a receiving profile-member 140 but do not extend in an inclined manner relative to the longitudinal axis of the profile-member but instead parallel therewith. These are inserted into corresponding recesses 142 in the retaining profile-member 144, as illustrated in FIGS. 20a to 20c. In order to achieve the tensioning effect described above in the case of a mutual relative movement of the profile-members, these recesses 142 also have inclined portions 146 on which the flaps 141 can slide under the tensioning effect until they are received in receiving slots 148 which define a predetermined desired position. This state in which the desired position has been reached is illustrated in FIG. 20c.

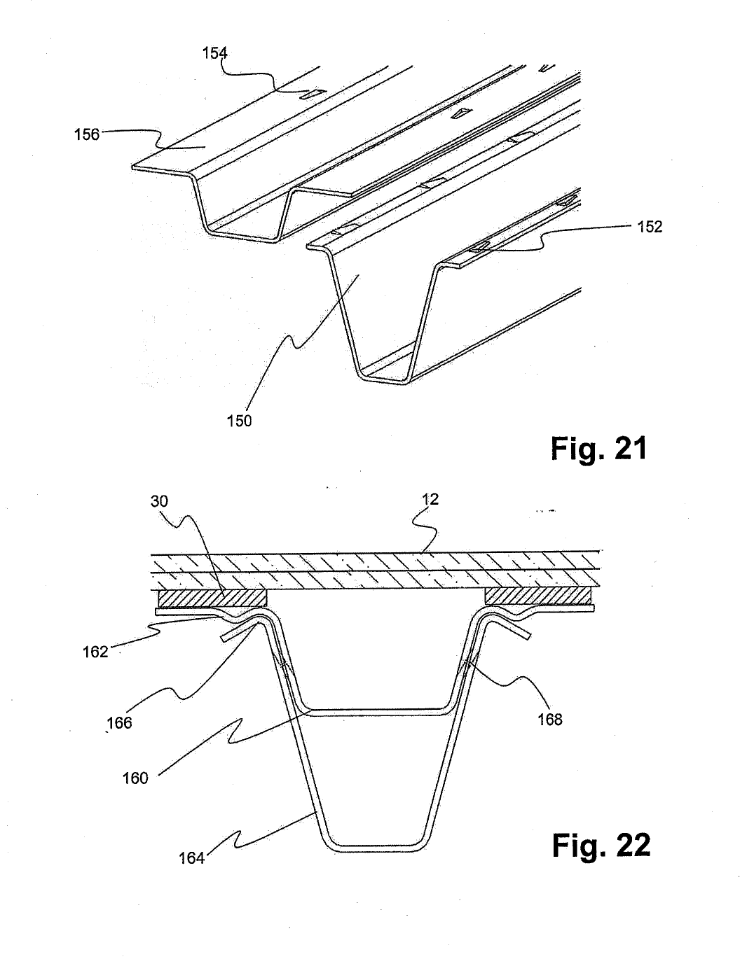

FIG. 21 illustrates another configuration of the invention in which the receiving profile-member is intended to be prevented from opening. To this end, wedge-like beads 152 are provided on the receiving profile-member 150 at the upper side of the profile-member and engage with corresponding wedge-like beads 154 on a retaining profile-member 156. This engagement also increases as a result of gravitational force during assembly owing to a relative movement between the retaining profile-member 156 and receiving profile-member 150.

Finally, FIG. 22 illustrates another configuration of the invention. It can be seen that a retaining profile-member 160 is fitted to the solar module 12 by means of the adhesive layers 30 and, in the region of the adhesive layers 30 close to the transition to the inclined trapezoidal faces, has recesses 162 which extend in the longitudinal direction of the profile-member. This retaining profile-member 160 is received in a receiving profile-member 164 which is folded with the upper free ends thereof at an acute angle at 166. With this folded region 166, it engages between the recesses 162 and the inclined trapezoidal faces of the retaining profile-member 160. The receiving profile-member 164 is thereby prevented from opening. Furthermore, it is possible to see engagement structures as described above on the inclined trapezoidal faces, for example, flaps or beads.

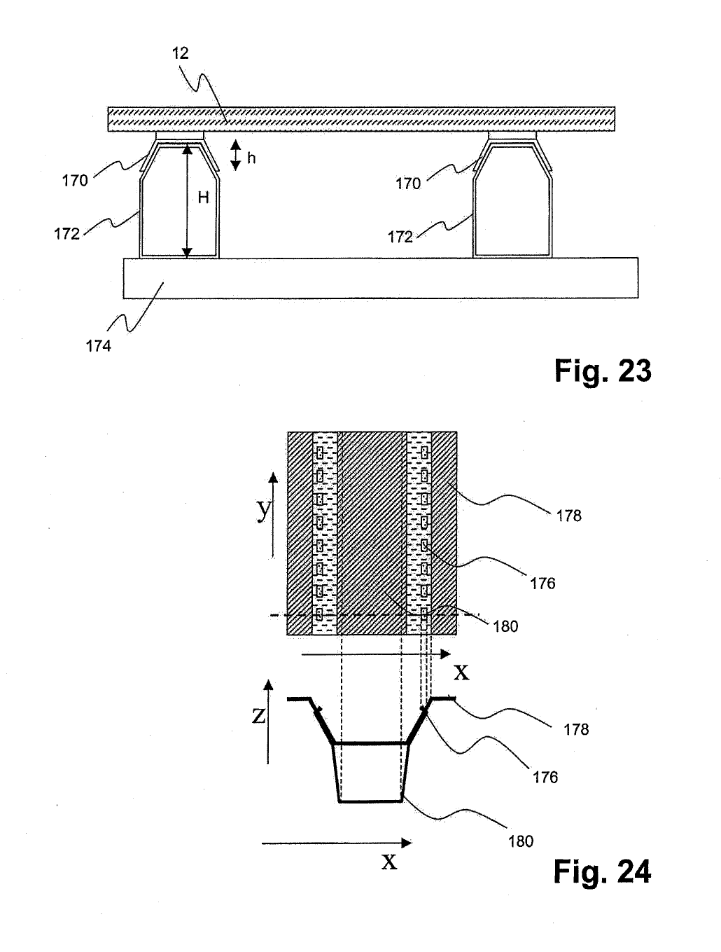

FIG. 23 illustrates another embodiment according to the invention in a view similar to FIG. 2, the receiving profile-members 170 being fitted to the solar module 12. The receiving profile-members 170 have only a relatively small height h. The receiving profile-members 170 receive retaining profile-members 172 which are constructed so as to have a significantly larger height H in order to achieve a high level of flexural strength. This is at least 1.5 times as high as the height h. The retaining profile-members 172 are themselves fixed to transverse struts 174 of the substructure.

FIG. 24 illustrates for an embodiment, as illustrated in FIGS. 17a to 17c, that, owing to a plurality of connection locations 176 between a retaining profile-member 178 and a receiving profile-member 180, the strength of the connection can be increased as necessary. This leads to more advantageous bending behaviour of the fixing structure which can be compared with the bending behaviour of a dual T-carrier which is well known in the field of mechanical engineering.

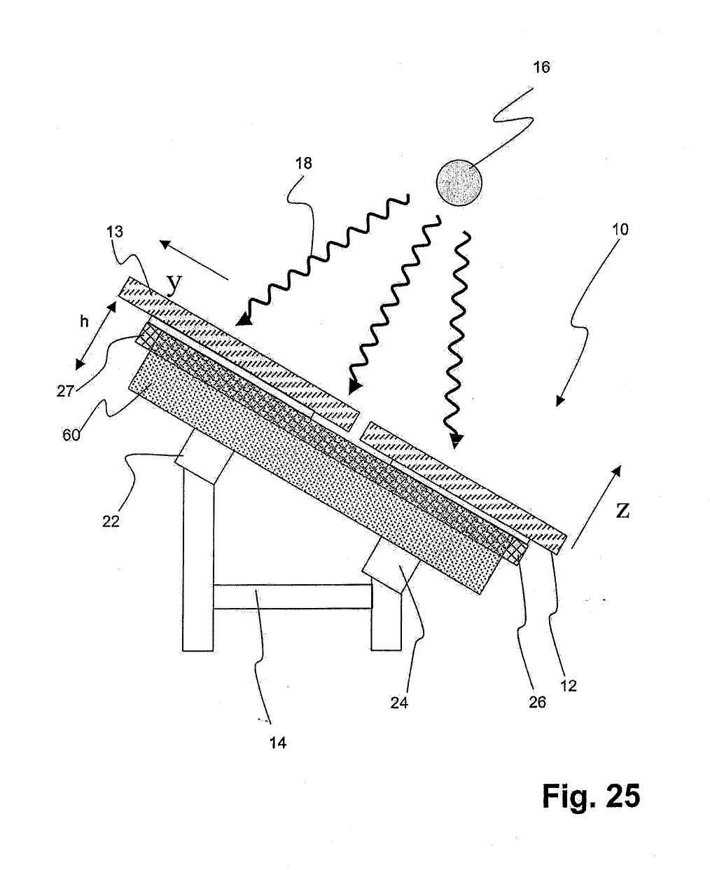

FIG. 25 illustrates another arrangement according to the invention in accordance with FIG. 7, but with two or more smaller solar modules 12 and 13 with retaining profile-members 26 and 27 which are arranged thereon being arranged on one and the same receiving profile-member 60.

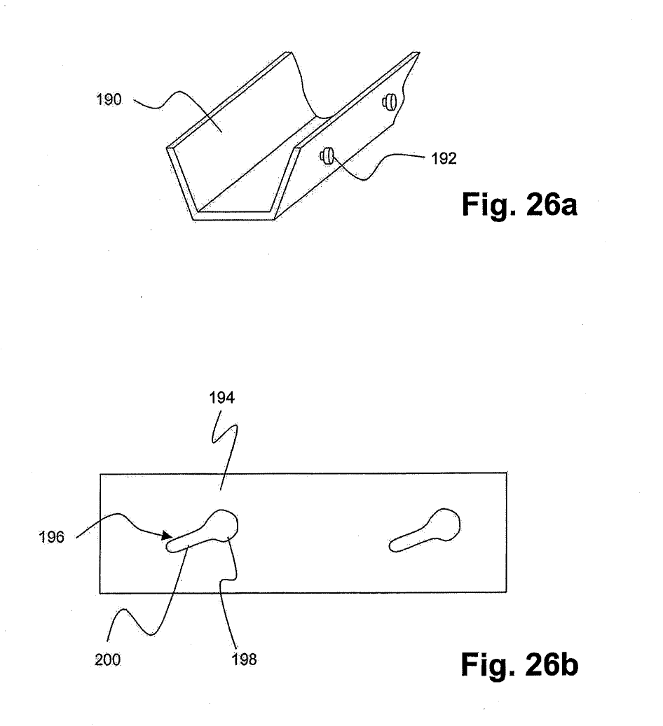

With the configuration according to the invention in accordance with FIGS. 26a and 26b T-bolts 192 with a head are fitted in each case to the retaining profile-member 190 at the solar module side and can be received in corresponding receiving openings 194 on a corresponding receiving profile-member 196 (shown in a lateral view in FIG. 26). Each receiving opening 194 has an introduction portion 198 which is as large as the diameter and a guiding portion 200 which is reduced in diameter and behind which the head of the T-bolt 192 which is introduced engages. Owing to the inclined path of the guiding portion 200, the tensioning effect mentioned several times above is achieved.

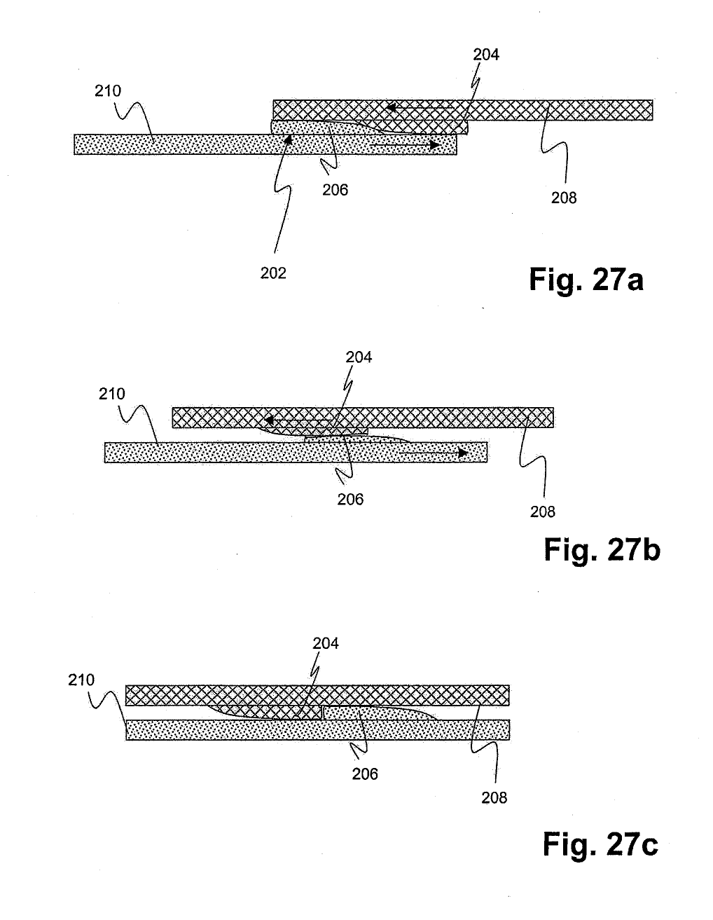

FIGS. 27a to 27c illustrate a locking structure 202, corresponding locking projections 204, 206 being fitted to a retaining profile-member 208 and to a receiving profile-member 210. When these two profile-members 204, 206 are joined together when the solar module is assembled, the locking projections may slide past each other with resilient deformation (FIG. 27a, b) and ultimately engage with each other (FIG. 27c). A connection is thus produced which can be released only with considerable effort and which can provide inter alia good protection against theft.

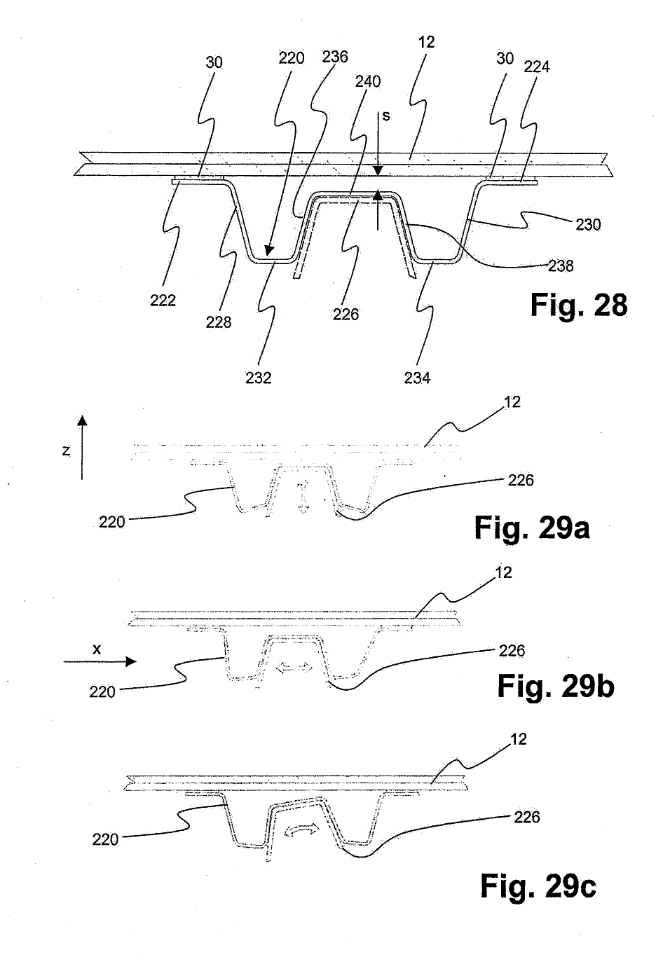

FIG. 28 illustrates another configuration of a solar module 12 according to the invention, in which a receiving profile-member 220 is fitted to the rear side of the solar module 12. The receiving profile-member 220 has a W-shaped configuration with two wing portions 222 and 224, which are fitted to the rear side of the solar module 12 with adhesive layers 30. Between the two wing-like portions 222 and 224, a receiving portion extends substantially centrally and a retaining profile-member 226 which is securely fitted to a substructure is received therein in a positive-locking manner. This retaining profile-member 226 is trapezoidal, substantially as described with reference to FIG. 2.

The receiving profile-member 220 at the solar module side has a plurality of portions. From the two wing portions, it first extends with a region 228, 230 which is positioned in an inclined manner relative to the wing portions 222, 224. This merges into portions 232, 234 which extend substantially parallel with the wing portions 222, 224 which two portions 236, 238 which extend inwards in an inclined manner adjoin. These two portions 236 and 238 which extend in an inclined manner then merge into a central portion 240 which extends substantially parallel with the wing portions 222 and 224. The portions 236, 238 and 240 form the receiving region for the retaining profile-member 226.

It can be seen in FIG. 28 that the region 240 opposite the wing portions 222 and 224 is recessed downwards, so that a spacing s is produced between the central portion 240 and the rear side of the solar module 12. That is to say, the central portion 240 is free relative to the solar module 12 and can move during resilient deformations of the profile-member 220, without touching the solar module 12.

The connection between the retaining profile-member 226 and receiving profile-member 220 is carried out in the same manner as described above for various embodiments, that is to say, by means of corresponding undercuts, beads or the like.

In FIGS. 29a to 29c, various examples of deformation can be seen, drawn to a slightly exaggerated scale. FIG. 29a illustrates that a tolerance compensation is possible in the Z direction with the receiving profile-member 220, for example, when a plurality of retaining profile-members 226 are arranged at different heights. Accordingly, the receiving profile-member 220 is deformed in such a manner that the two portions 232 and 234 are deflected upwards and thus height differences can be compensated for in accordance with the double-headed arrow, with the solar module 12 remaining substantially in the same position. The double-headed arrow according to FIG. 29a indicates that tolerance compensation can also occur in a downward direction.

FIG. 29b illustrates the possibility of a lateral tolerance compensation in the X direction. In the case of such a tolerance compensation, for example, when the retaining profile-member 226 is not in the desired position thereof in the X direction, the retaining profile-member 220 can become resiliently deformed and thus provide adequate receiving of the retaining profile-member 226.

Finally, the illustration according to FIG. 29c illustrates the possibility of a tolerance compensation with the retaining profile-member 226 having a slightly rotated or tilted orientation on the substructure. The flexibility or resilient deformability of the receiving profile-member 220 can be adjusted as desired. It is thus possible for the connection regions between the portions 222 to 240 to be adjusted as desired by means of appropriate selection of materials, adjustment of the material thickness, geometric deformation (by means of sharp-edged or harmonious transitions and by fitting beads or the like). It is thus possible to use, for example, a slightly resiliently deformable thin-walled material in order to ensure a tolerance compensation in accordance with FIGS. 29a to 29c with weak forces. On the other hand, the transition regions between the portions 222 to 240 can be constructed so as to be more rigid by constructing the receiving profile-member with a correspondingly greater wall thickness. The individual portions 228 to 240 can also be constructed as required with larger or smaller wall thickness and with or without reinforcement ribs or beads or by partially removing material in order to specifically adjust the deformation behaviour thereof as required.

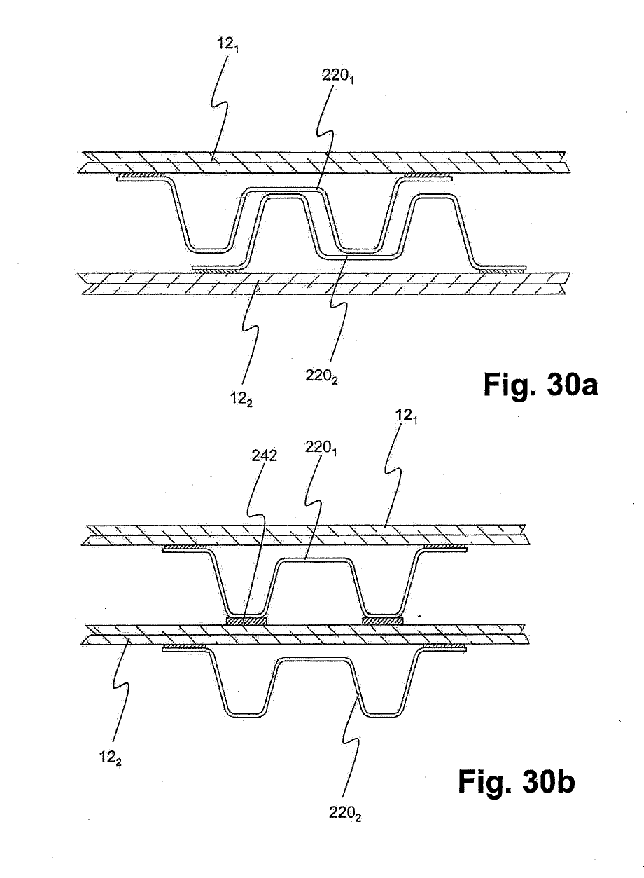

The geometry of the receiving profile-member 220 according to FIG. 28 also affords advantages with respect to transporting a plurality of solar modules. For instance, FIG. 30a illustrates that two solar modules 12₁ and 12₂ are fitted to each other with associated receiving profile-members 220₁ and 220₂, respectively, in such a manner that the two receiving profile-members 220₁ and 220₂ face each other and mutually engage. These solar modules can thus be stacked one on top of the other in a space-saving manner and without the risk of their damaging each other.

Another arrangement in which the solar modules 12₁ and 12₂ are stacked one on top of the other in the same direction is illustrated in FIG. 30b. In this illustration, it can be seen that, in order to protect the surface of the lower solar module 12₂, cushions or elements 242 of resiliently cushioning material, for example, layers of foam, are provided.

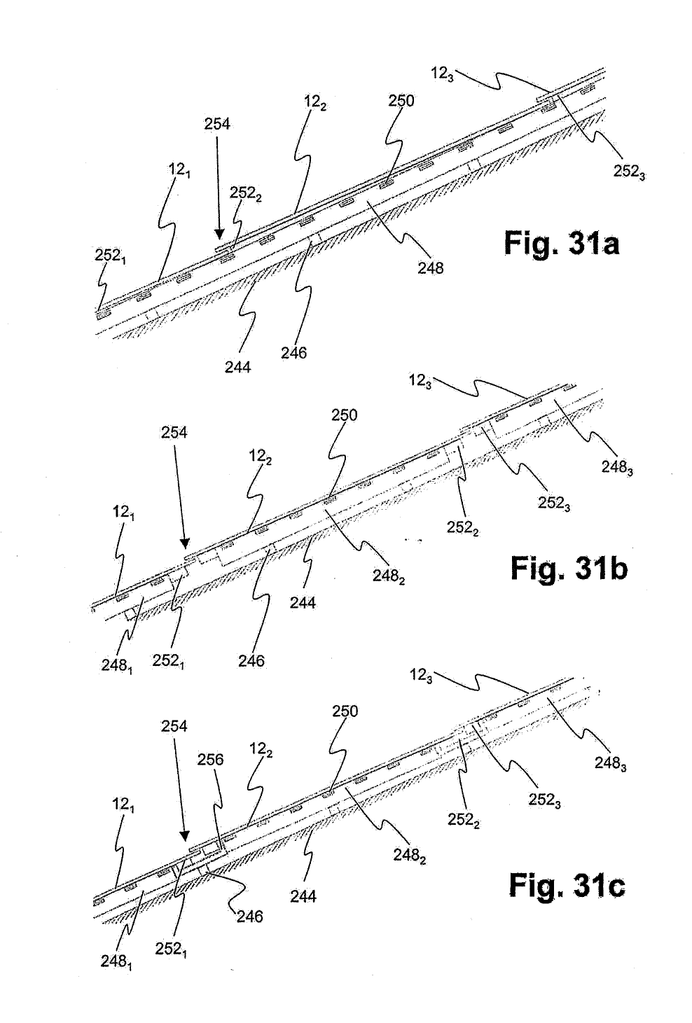

FIG. 31a illustrates an arrangement in which a plurality of solar modules 12₁, 12₂, 12₃ are fitted to a roof 244. On the roof there are provided transverse struts 246 which fix elongate receiving profile-members 248 to the roof 244. The retaining profile-members have engagement formations 250, as already described above. It can further be seen that retaining profile-members 252₁, 252₂, 252₃ are fitted to each solar module 12₁, 12₂, 12₃. These have a height which decreases in a longitudinal and upward direction, so that the respective lower portion of the associated solar module is located with a greater spacing from the upper portion of the retaining profile-member 248 than the upper side of the solar module which is in abutment therewith. The solar modules 12₁, 12₂, 12₃ are thereby arranged in the manner of scales on the roof 244 and overlap in overlapping regions 254 on top of each other which is advantageous, in particular with an arrangement on roofs. Rainwater can thereby flow away from the roof, without flowing through horizontal intermediate spaces between adjacent modules. Consequently, the roof can ideally be covered purely with solar modules.

FIG. 31b illustrates a similar situation to FIG. 31a, but with the receiving profile-members 248₁, 248₂, 248₃ being constructed with a height which decreases in an upward direction, so that the inclined position which has already been described with reference to FIG. 31a is produced.

Finally, it is possible to see in FIG. 31c an arrangement in which a separate receiving profile-member 248₁, 248₂, 248₃ is associated with each solar module 12₁, 12₂ and 12₃, respectively. They are provided with support elements 256 which provide an inclined positioning of the receiving profile-members 248₁, 248₂, 248₃ relative to the plane of the roof 244 so that the scale-like arrangement of the individual solar modules 12₁, 12₂ and 12₃ is again achieved.

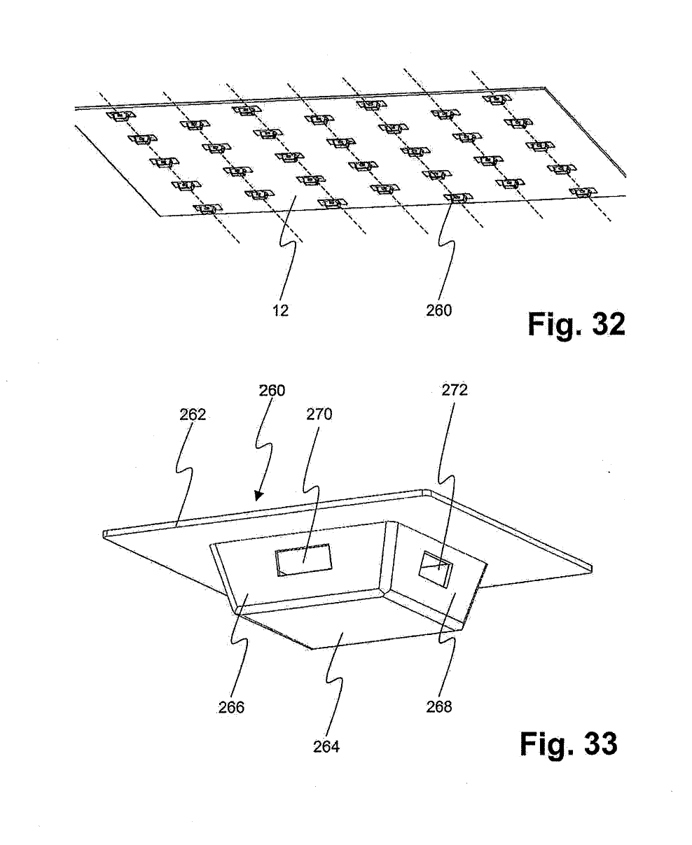

FIG. 32 illustrates another solar module 12, at the rear side of which individual retaining profile-member elements 260 are arranged. These extend along broken lines and are aligned along these lines so as to be in alignment with each other. FIG. 33 illustrates such a retaining profile-member element 260 in detail. It has a fixing plate 262, which can be fitted to the rear side of the solar module 12 by means of adhesive-bonding. In the central region thereof, the retaining profile-member element 260 has a box-like hollow projection 264 whose lateral walls 266, 268 are arranged in an inclined manner. Recesses 270, 272 are provided in each case in the side walls. The inclined arrangement and the recesses also apply to the concealed side walls which are not illustrated in FIG. 33. Such retaining profile-member elements 260 are similarly received, as set out above with respect to the elongate retaining profile-members, in corresponding receiving profile-members and fixed in the manner described above via the recesses 270, 272.

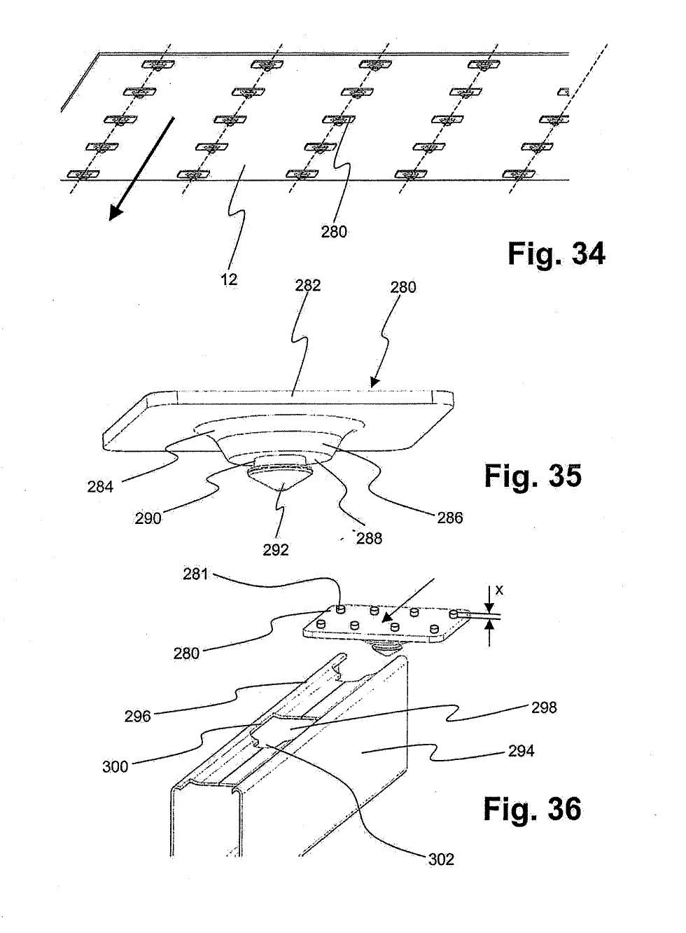

A similar arrangement is also illustrated in FIG. 34. In this instance, the solar module 12 is provided with retaining profile-member elements 280 in the same manner as described with reference to FIG. 32. FIG. 35 is an enlarged view of such a retaining profile-member element. This again has a fixing plate 282 by means of which it can be fixed to the lower side of the solar module 12 by means of adhesive-bonding. In the central region of this plate 282, a projection extends downwards and first extends in a rounded portion 284 from the plate 282 and then merges continuously into a frustoconical portion 286. This terminates in a plateau 288. From the plateau 288, there extends a cylindrical portion 290 which a conical head 292 adjoins whose basic diameter is significantly greater than the diameter of the cylindrical portion 290 so that an undercut is produced at the rear side of the head 292.

Such a retaining profile-member element 280, as illustrated in FIG. 36, can be inserted into a receiving profile-member 294 which has recesses 298 at the upper side 296 thereof. These recesses 298 have a wide portion 300 which continues smoothly into a narrower portion 302 via inclined introduction faces. The wide portion 300 of the opening 298 is sized in such a manner that the head 292 of the retaining profile-member element 280 can be inserted with clearance. Consequently, the retaining profile-member element 280 is displaced in accordance with the arrow according to FIG. 36 along the receiving profile-member 294 so that the cylindrical portion engages in the narrower portion 302 of the opening 298, the head 292 engaging behind the opening with the undercut thereof so that the retaining profile-member element 280 is securely anchored in the receiving profile-member 294 in the manner of a key/lock principle. The openings 298 can be arranged in an inclined manner relative to the longitudinal axis of the receiving profile-member 294 so that, when the head 292 is inserted into the opening 298 in accordance with the arrow according to FIG. 36, a tensioning effect is achieved, with which the solar module 12 is drawn more powerfully towards the receiving profile-member 294 as the head 292 is pushed further into the narrower portion 302 of the opening. In the configuration according to FIGS. 34 to 36, the retaining element profile-member 280 may be produced from plastics material, metal, rubber or other materials. It may have resilient properties in order to thus achieve tolerance compensation.

In FIG. 36, it can further be seen that, at the side of the retaining profile-member element 280 which is fitted to the solar module 12, a row of local projections 281 with a predetermined height x is provided. These projections 281 serve to achieve a predetermined spacing x relative to the solar module 12, when the retaining profile-member elements 280 are adhesively-bonded thereto. That is to say, the height x of the projections 281 defines the thickness of the adhesive layer between the solar module 12 and retaining profile-member element 280.

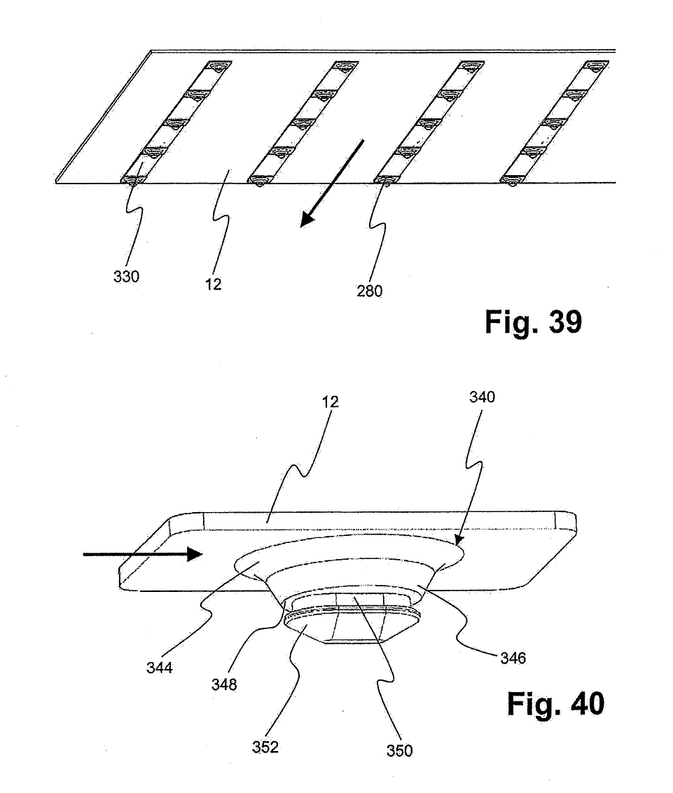

It should be noted that a plurality of retaining profile-member elements 280 can also each be fitted to a strip or rail 330 which is then fitted in its entirety to the rear side of the solar module 12. This principle can be seen in FIG. 39. The arrow indicated in FIG. 39 illustrates the preferred assembly direction, in accordance with FIG. 34 or FIG. 36, respectively.

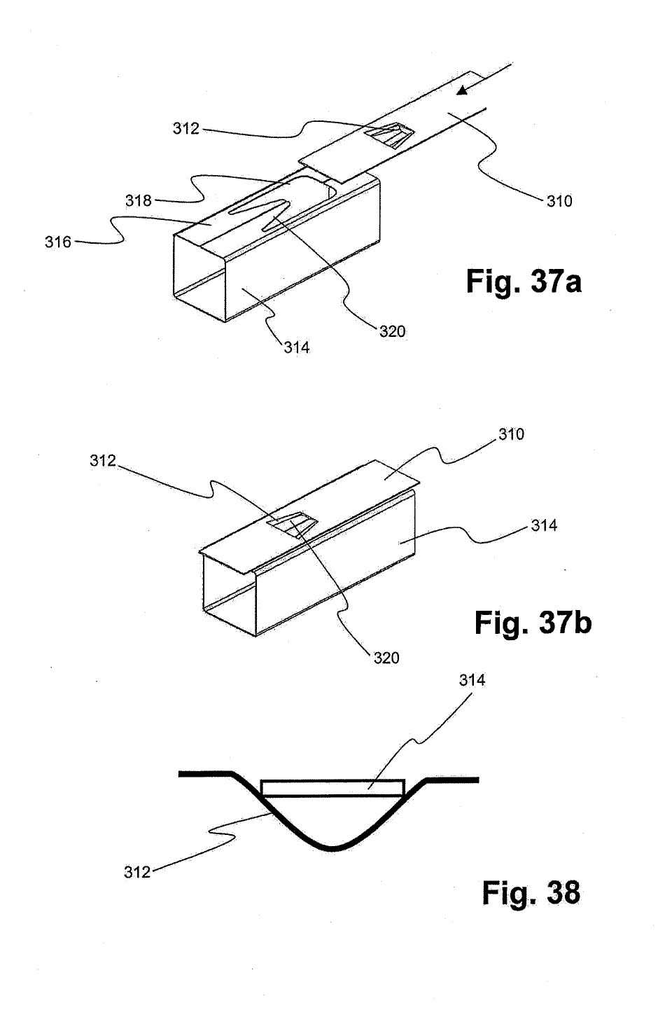

In FIGS. 37a, b, another configuration of the invention can be seen in which a substantially planar retaining profile-member 310 which can be fitted to the rear side of a solar module which is not illustrated by means of adhesive-bonding, is provided with notches which form a type of pocket 312. The receiving profile-member 314 has, at the upper side 316 thereof, recesses 318 which are constructed so as to be so wide that they can receive, within their width with clearance, the pockets 312 which protrude downwards from the retaining profile-member 310. Tongues 320 protrude into the openings 318 but extend in the plane of the upper side 316 of the receiving profile-member 314.

These tongues taper to a point. Similarly, the pockets 312 also taper upwards in a conical manner.

The assembled state comprising the retaining profile-member 310 and receiving profile-member 314 can be seen in FIG. 37b, the tongues 320 engaging in the pockets 312 in a positive-locking manner. FIG. 38 illustrates the situation in section, the pocket 312 engaging behind the tongue 320 and thus retaining the retaining profile-member 310 securely on the receiving profile-member 314. Again, owing to the conical configuration of the tongues 320 and pockets 314, a tensioning effect can be achieved, which is supported by the gravitational force acting on the solar module which is provided with the retaining profile-member 310.

FIG. 40 illustrates an alternative configuration of a retaining profile-member element 340 which is constructed in a similar manner to the retaining profile-member element 280 according to FIG. 35. In contrast to the retaining profile-member element 280 according to FIG. 35, however, the retaining profile-member element 340 does not have any fixing plate 342, by means of which it is secured to the lower side of the solar module 12 by means of adhesive-bonding. Instead, the retaining profile-member element 340 is adhesively-bonded directly to the solar module 12 with the oval rounded portion 344 thereof. From this portion 344, the retaining profile-member element 340 then extends continuously into a tapering portion 346 having an oval surface-area. This terminates in a plateau 348. From the plateau 348, a cylindrical portion 350 having an oval surface-area extends, which a corresponding head 352 adjoins. The base of the head 352 extends over the surface-area of the cylinder 350 so that an undercut is produced at the rear side of the head 352 facing the plateau 348.

This retaining profile-member element 340 can be fitted to the rear side of a solar module 12, in the same manner as described with reference to FIG. 34 or 39. However, it has the advantage that, owing to the oval or elongate surface-area of the cylindrical portion 350, better guiding is produced for the solar module during assembly in the corresponding opening (see reference numeral 302 in FIG. 36) in the receiving profile-member 294, if the solar module is displaced in the movement direction indicated with the arrow relative to the receiving profile-member in such a manner that the retaining profile-member element 340 engages in the receiving profile-member in an anchoring manner. In addition, owing to the relatively large mechanically effective region, a greater force is able to act on the retaining profile-member element 340.

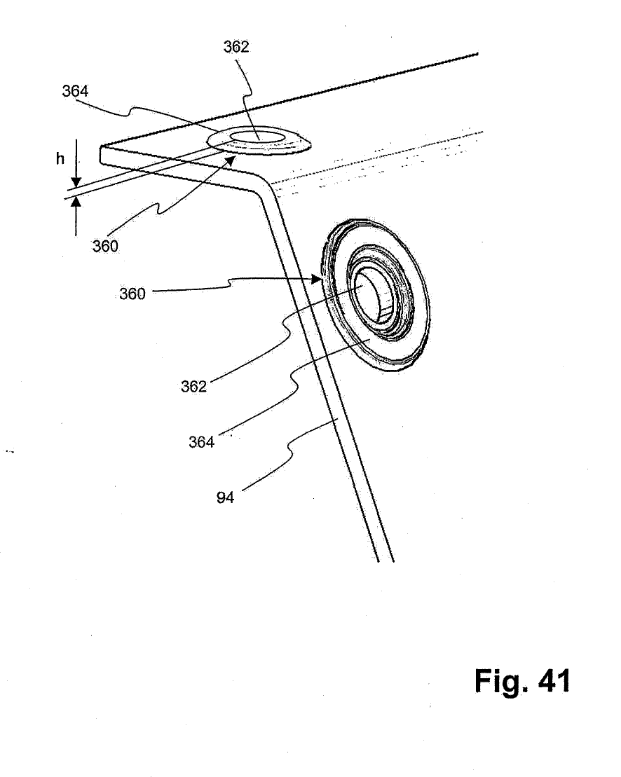

FIG. 41 illustrates a corner region of a receiving profile-member which can generally be constructed in terms of its shape, for example, in the same manner as the receiving profile-member 94 of FIG. 13. However, the receiving profile-member, on those surfaces which co-operate with the retaining profile-member fitted to the solar module 12, is in each case provided with local projections 360. These local projections protrude over a small height h from the face which surrounds them and may be constructed in a closed plateau-like manner or, as illustrated, have an opening 362 which is arranged centrally in the embodiment illustrated but which can also be positioned eccentrically. They may be circular, the central opening 362 being surrounded by a circular, substantially flat plateau 364. The transition from the face which surrounds the projections 360 to the plateau 364 and from the plateau 364 to the central opening 362 is constructed in a constant and harmonious manner so that there are no sharp edges.

The local projections 360 can be produced by shaping the material of the profile-member. However, it is also possible to produce these projections by subsequently fitting corresponding disc-like members, for instance by means of welding or adhesive-bonding. The local projections can also additionally or alternatively be fitted to the other profile-member in each case, in this instance the retaining profile-member. They can be provided in relatively large numbers with regular spacing in the longitudinal direction of the respective profile-member.

The local projections 360 have the advantage that they retain the receiving profile-member and retaining profile-member with minimal spacing relative to each other. It is thereby possible for moisture which accumulates owing to precipitation or thermodynamic processes, such as condensation water or the like, to flow away through a small gap between the retaining profile-member and the receiving profile-member. Furthermore, air can circulate between these profile-members so that a permanent accumulation of moisture between the receiving profile-member and retaining profile-member can be prevented and the effects of corrosion can thereby be prevented in the long-term. Furthermore, the central opening 362 ensures specific discharge of water and an increase in the air circulation. The height h which determines the dimension of the gap is selected to be so small (in the region of 1 mm) that the abutment of the receiving profile-member and retaining profile-member and the retention properties are not impaired but instead a circulation of air and discharge of water which prevents corrosion are adequately ensured.

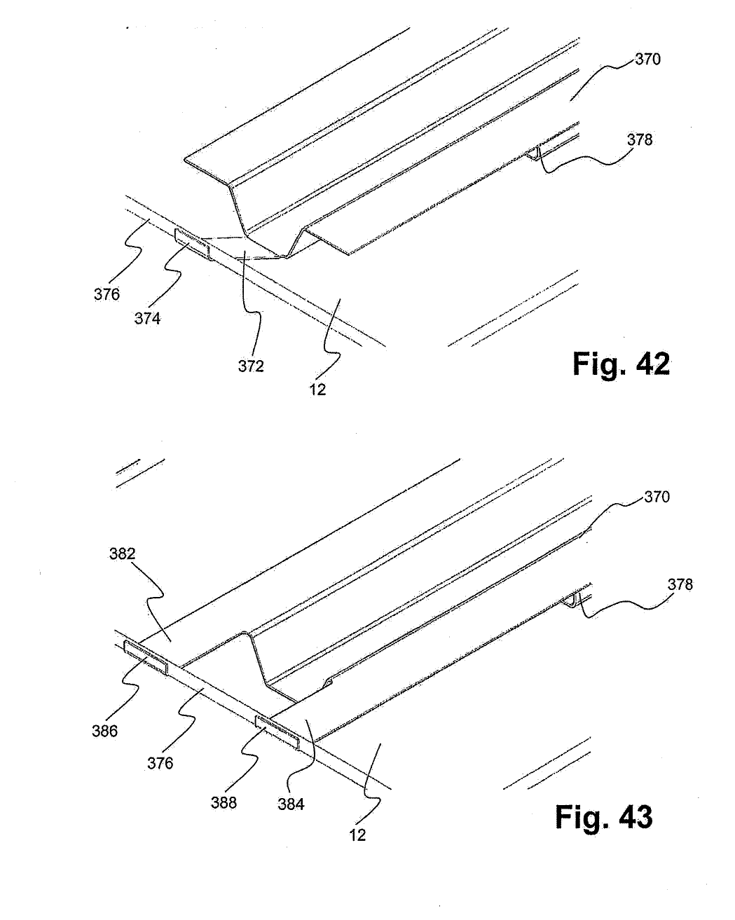

FIGS. 42 to 44 illustrate developments of the receiving profile-member according to the invention, which is fitted to the solar module 12 which is illustrated in a transparent manner. It can be seen that, from the receiving profile-member 370 according to FIG. 42, from the portion thereof remote from the solar module 12, a gripping flap 372 in each case extends in an inclined manner towards the solar module 12 and engages with an angled portion 374 at the front side 376 of the solar module. It is thereby possible for the retaining profile-member 370 to be retained in a predetermined relative position with respect to the solar module 12. This is ensured in particular when a corresponding retaining flap 362 with an angled portion 374 is arranged at the opposite end of the retaining profile-member 370 (not illustrated) and engages around the opposing front side of the solar module 12. It is thereby possible to permanently achieve a predetermined positioning of the retaining profile-member 370 with respect to the solar module. It is also ensured that this positioning also remains for the entire service life of the solar module and that no undesirable migration occurs, for example, owing to non-optimum fitting of the retaining profile-member 370 to the solar module 12 with a layer of adhesive whose retention function deteriorates. Furthermore, it is thereby also possible to prevent mutual displacement of the individual layers, from which a solar module is composed and which are fixed to each other by means of lamination.

For the sake of completeness, it should be mentioned that the receiving profile-member 378 which receives the retaining profile-member 370 can still be seen in outline form in FIG. 42. For reasons of simplification of the drawings, no engagement formations are illustrated in FIGS. 42 to 44.

FIG. 43 illustrates an alternative configuration of a retaining profile-member 380 in which the two leg portions which are fitted to the solar module 12 are each provided at the end with gripping flaps 382 and 384 which extend in the direction towards the front side of the solar module 12 and have an angled portion 386, 388 which engages around the front side 376 in each case. The effect is the same as that described with reference to FIG. 42. A predetermined relative position between the retaining profile-member 380 and solar module 12 can be permanently achieved and undesirable displacement of plates which are laminated together to form the solar module is prevented. Furthermore, the angled portions 386 and 388 also act as edge protection for the edge or front side 376 of the solar module 12 during transport and assembly. For example, the solar module 12 can be positioned on the angled portions 386, 388, without there being any risk of the front side 376 thereof becoming damaged.

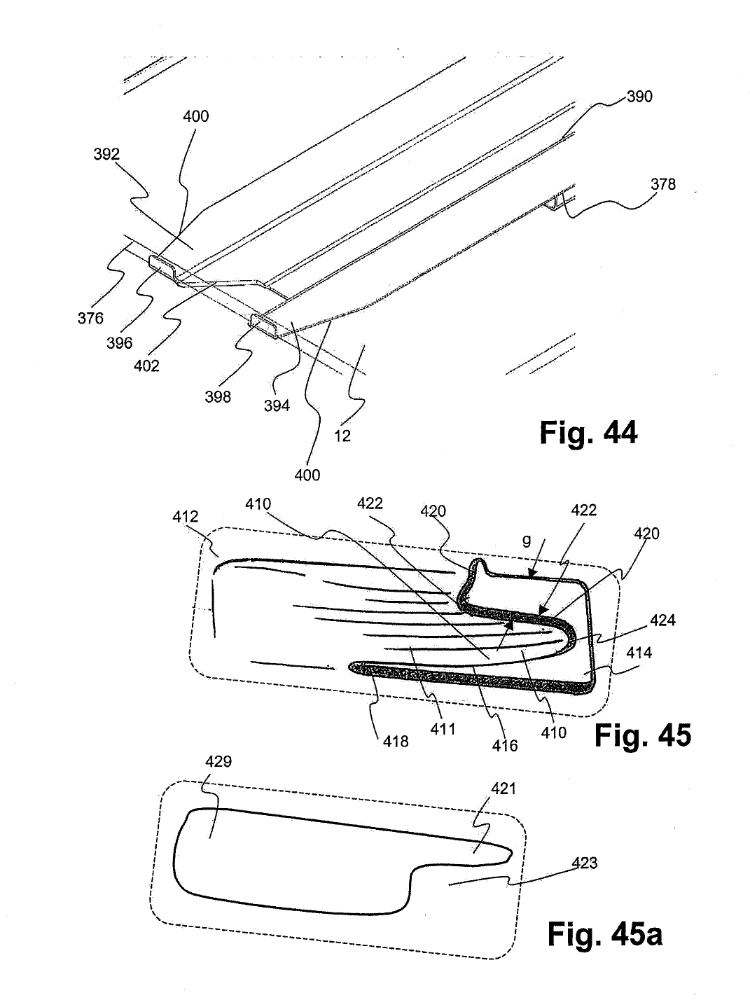

FIG. 44 illustrates a configuration similar to that according to FIG. 43. In this configuration, the retaining profile-member 390 is again provided with two gripping flaps 392, 394 which engage around the front side 376 of the solar module 12 with angled portions 396 and 398. The difference between the configuration according to FIG. 43 and the one according to FIG. 44 is that the angled portions 396 and 398 are constructed so as to be relatively short and the retaining profile-member 390 has profile-member portions 400 and 402 which extend in an inclined manner relative to the angled portions 396, 398. The profile-member portions 400 extend in the plane of the regions which are used for fitting to the solar module 12. The profile-member portions 402 extend in an inclined manner from the narrow base region to the angled region 396 or 398.

FIG. 45 illustrates the geometry of a spoon-like flap 410 on a receiving profile-member or retaining profile-member. The engagement formation according to FIG. 45 has been achieved by means of a combination of punching and material deformation. A free region 414 has been punched from the receiving profile-member or retaining profile-member 412. The tongue-like flap 410 with a continuously rounded contour is thus produced. This flap 410 is bent from the material plane of the surrounding material of the retaining profile-member 412 by means of a shaping process about the height g and is connected to this surrounding material in a base region 418 and by means of a connection web 420. The path from the material plane of the surrounding profile-member is illustrated by profile lines 411. The flap 410 has a convex lower flank 416 and a substantially linear upper flank 422 which meet at an apex 424.

The other profile-member from the receiving profile-member and retaining profile-member has an opening 429, as illustrated in FIG. 45a and also in FIG. 20a. For assembly, the flap 410 of one profile-member is moved into the opening 429 of the other profile-member and displaced, by means of relative mutual displacement of the profile-members, in such a manner that the connection region 420 is introduced into a corresponding receiving slot 421. The flap 410 engages behind a retaining portion 423 of the profile-member adjoining the receiving slot 421 and thus ensures secure mutual retention of the retaining profile-member and receiving profile-member.

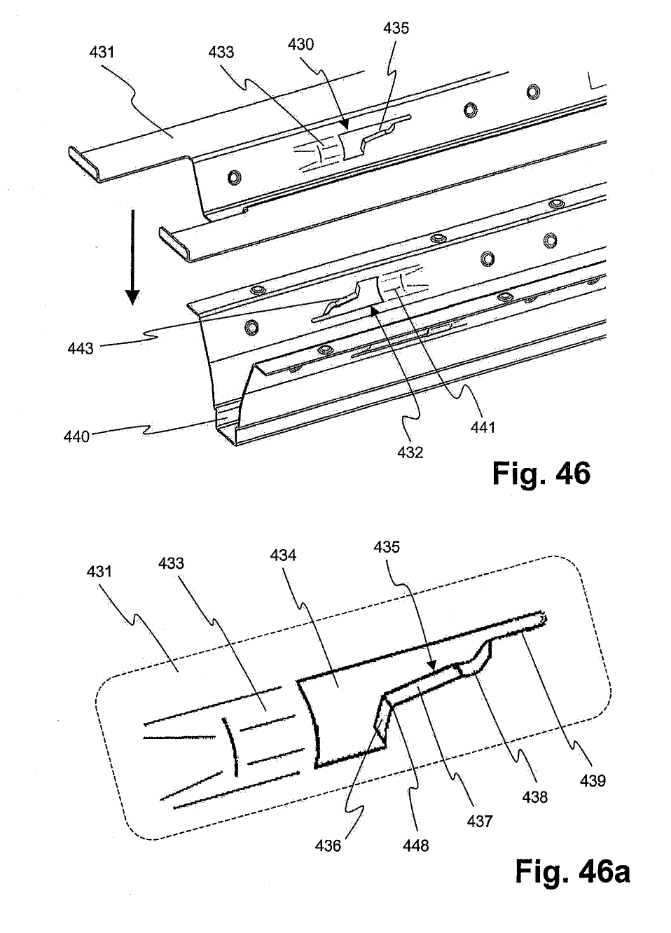

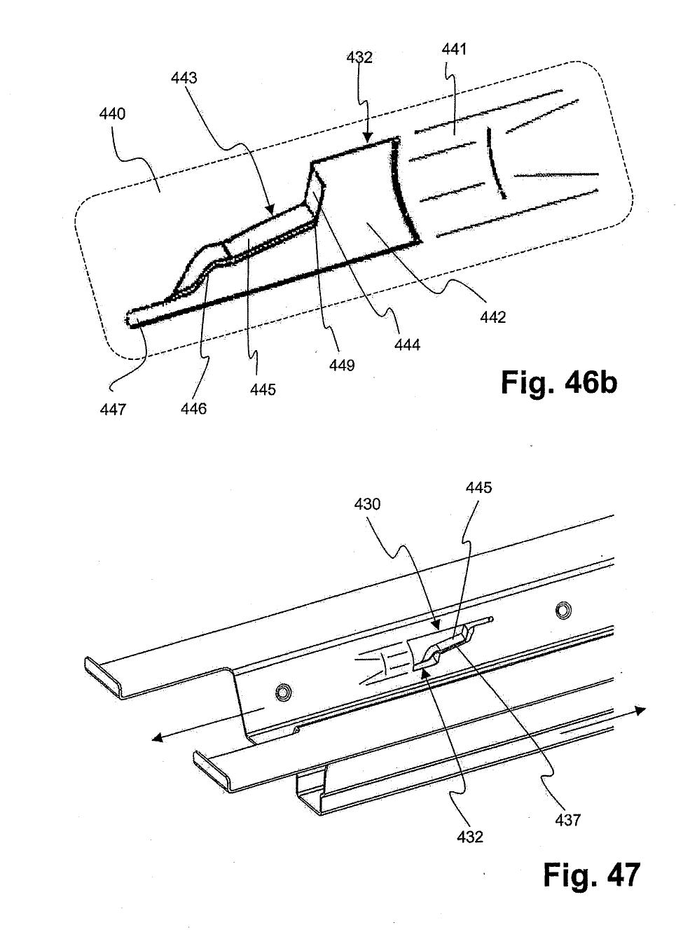

FIG. 46 illustrates another configuration of the invention in which engagement formations 430 and 432 are constructed on each profile of the receiving profile-member 440 and retaining profile-member 431 respectively and are described in detail with reference to FIGS. 46a and 46b. In FIG. 46, the receiving profile-member 440 and retaining profile-member 431 are illustrated in a state of pre-assembly, the receiving profile-member 440 in contrast receiving the retaining profile-member 431 in FIG. 47, the two engagement formations 430 and 432 mutually engaging.

The engagement formation 430 which is illustrated in FIG. 46a and which is constructed as part of the retaining profile-member 431 is arranged in the region of a local rounded curvature 433. It comprises a recess 434, the lower contour of this recess 434 in FIG. 46a being constructed in a stepped manner. The material of the retaining profile-member 431 is stamped in this region so that a stepped ramp 435 is produced which has a first abutment portion 436 which is steeply inclined relative to the longitudinal axis of the profile-member, a flatter tensioning portion 437 and a curved terminal portion 438. The terminal portion 438 is constructed with a slight recess and merges harmoniously into a slot 439.

The engagement formation 432 on the receiving profile-member 440 is constructed in a complementary manner. It also has a local rounded curvature 441 which adjoins a recess 442. This recess 442 has a stepped ramp 443 with a steeply inclined abutment portion 444 and a less steeply inclined tensioning portion 445 relative to the longitudinal axis. A rounded terminal portion 446 again adjoins this, by means of which the ramp profile-member harmoniously terminates via a small recess and merges into a slot 447.

If the two profile-members 431 and 440 are placed one inside the other, as illustrated in FIG. 46 in the pre-assembled state (see arrow), it can be seen that the two curvatures 433 and 441 are constructed in a concave manner relative to each other. This makes it possible to insert the outwardly protruding ramp profile-member 435 in the region of the curvature 441 which is concave relative thereto, and the inwardly protruding ramp profile-member 443 into the region of the curvature 433 which is concave relative thereto, without impeding contact of the receiving profile-member 440 and retaining profile-member 431 over the ramp profile-members 435 and 443.

Consequently, both engagement formations 430 and 432 can then be moved towards each other in such a manner that the less inclined ramp portions 437 and 445 ultimately come into contact. The corresponding relative movement between the receiving profile-member and retaining profile-member is illustrated by the arrows in FIG. 47. The two ramp profile-members 435 and 443 engage one behind the other until finally the two terminal portions 438 and 446 come into contact with the facing, more inclined ramp portions 436 and 444 of the other profile-member, respectively. The receiving profile-member 440 and retaining profile-member 431 thus reach a predefined end position, the two ramp profile-members 435 and 443 providing a defined abutment.

In a development of the invention, it is possible for the transition edge 448 or 449 to be constructed with a slight protrusion between the steeply inclined ramp portion 436 or 444 and the less steeply inclined ramp portion 437 or 445 (not illustrated). This can engage in the harmonious recess in the terminal portion 438 or 446 in the manner of a locking connection and thus provide a defined end position.

The configuration according to FIGS. 46, 46a, 46b and 47 is distinguished by being particularly easy to assemble. It is obvious that the engagement profile-members 430 and 432 are arranged at both sides of the respective profile-member and are provided in large and corresponding numbers with fixed axial spacing relative to each other along the length of the respective profile-members. It is thereby possible for a defined and fixed coupling to be achieved over the entire length of the mutually engaging receiving profile-members and retaining profile-members. Owing to the inclined portions 445 and 437 which engage with each other, a mechanical tensioning effect is achieved, that is to say, the two profile-members are pressed towards each other accordingly when one is inserted in the other on wedges which slide over each other. When a solar module (not illustrated) which is fitted to the retaining profile-member 431 is arranged so as to be inclined relative to the horizontal, the downward force which is produced by the inclination in combination with the ramp portions 437 and 445 which extend in an inclined manner provides a powerful permanent tensioning effect. However, the retaining profile-member 431 can readily be removed from the receiving profile-member 440 without being destroyed, for example, when the solar module is intended to be repaired or replaced.

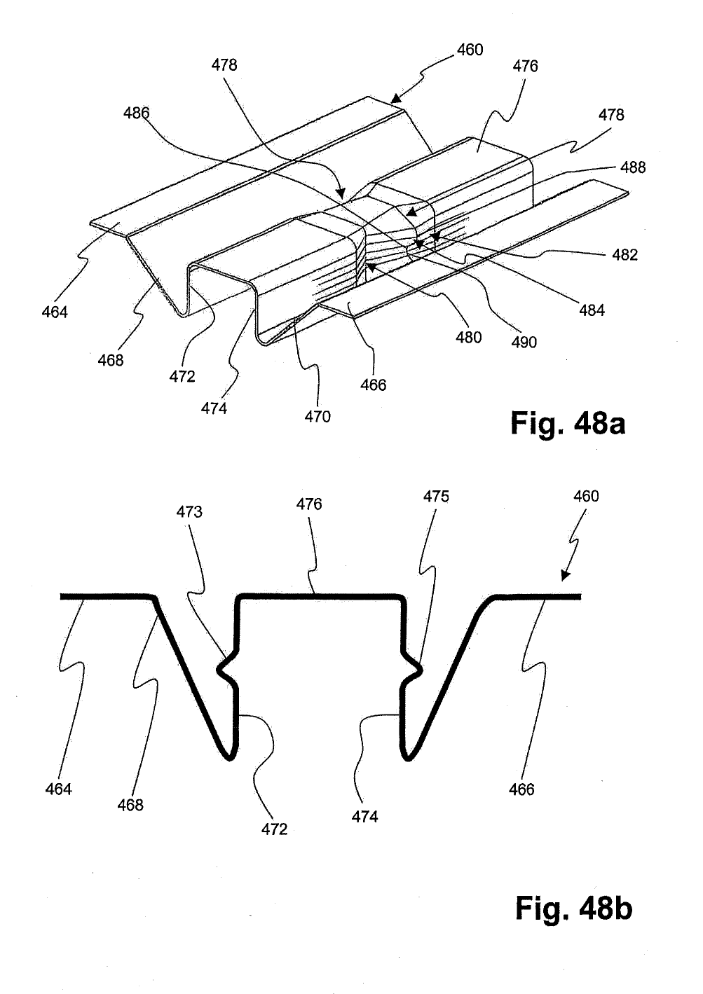

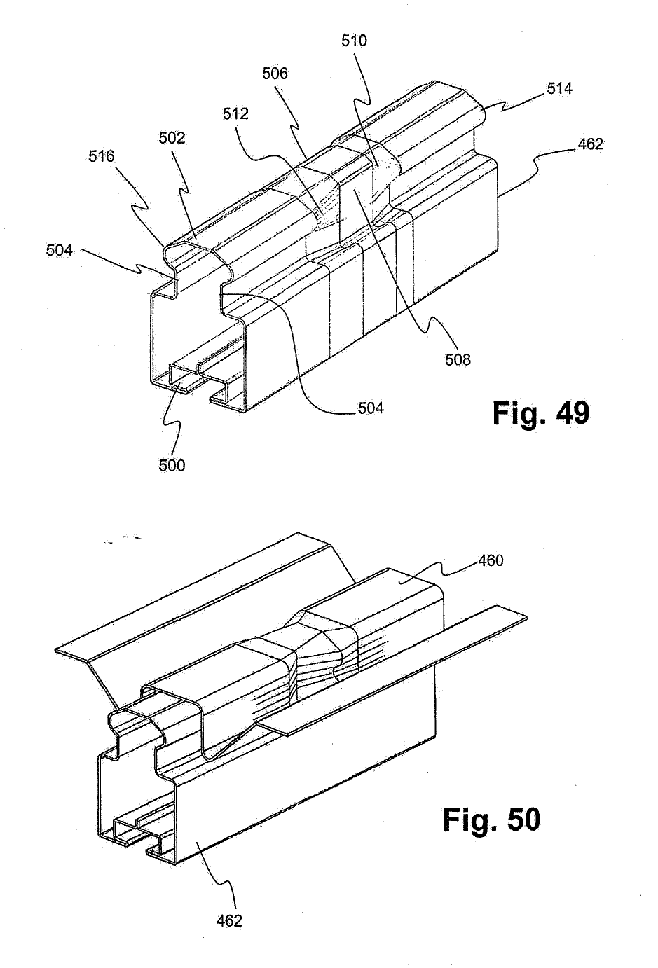

FIGS. 48 to 50 illustrate another configuration, FIG. 48 illustrating the receiving profile-member 460 which is to be fitted to the solar module and FIG. 49 the retaining profile-member 462 which is to be fitted to the substructure construction. FIG. 50 illustrates the assembled state between the retaining profile-member 462 and receiving profile-member 460.

In detail, the receiving profile-member 460 according to FIG. 48 has two horizontally extending profile-member portions 464 and 466 which can be fitted to the rear side of a solar module by means of adhesive-bonding. These merge via inclined profile-member portions 468 and 470 into a receiving region which has a box-like profile formed by vertical legs 472, 474 and a horizontal leg 476. The box-like profile is open in a downward direction. Substantially in the central region of the profile-member section according to FIG. 48, a deformed portion 478 is illustrated. This has a first conical portion 480, conically tapering faces being provided both in the region of the vertical webs 472 and 474 and in the region of the horizontal web 476. At the opposite end of the deformed region 478, that is to say, the region 482, conical faces are also provided. However, this region has protruding walls 484 at both vertical webs 472 and 474. The walls 484 are constructed in such a manner that a profile line 486 which extends transversely relative to the longitudinal direction has an S-shaped path with a protruding rounded portion 488 and a corresponding recessed rounded portion 490.

FIG. 49 illustrates the retaining profile-member which can be fitted to the substructure construction according to FIG. 7. It is constructed in a box-like manner. In the lower region thereof, it has an undercut recess 500 in which head screws or corresponding disc-like elements having a thread can be displaceably received in order to fit it to the substructure construction so as to be displaceable in a pre-assembled state, but secure after the fixing screws have been tightened.

At the opposite upper portion, the retaining profile-member 462 has a head region 502 which has undercuts 504. The head region 502 is constructed in a rounded manner. In the central region of the profile-member section according to FIG. 49, the head region is also provided with a deformed portion 506. This deformed portion has, in the central portion thereof, a straight box-like portion 508. From this box-like linear portion, faces which extend in a correspondingly inclined manner extend as far as the head-like portion 502. Particular attention should be paid to the transition regions which are characterised by beam-like profile lines 510 and 512 which merge from the box-like portion 508 into rounded corner regions 514 and 516 of the head region 502.

For assembly, the solar module is positioned with the receiving profile-members 460 on the retaining profile-members 462 in such a manner that the deformed region 478 engages in the box-like region 506. Subsequently, the solar module is displaced in the longitudinal direction of the retaining profile-member 462. The inner side of the walls 484 engages with the region 510 until finally the portion of the round region 514 which adjoins the region 510 of the retaining profile-member engages with the wall-like region 484. A positive-locking engagement is thereby ensured between the receiving profile-member and the retaining profile-member which prevents lifting of the solar module and provides secure engagement.

Two or more such deformed regions may be provided on each profile-member in the longitudinal direction thereof, the spacings of these regions on the retaining profile-member and the receiving profile-member corresponding. During assembly, a plurality of engagement locations are thereby produced in the longitudinal direction of the individual profile-members and provide secure mutual retention of the profile-members and consequently the solar module on the substructure construction.

FIG. 48b is a front view of a base member of a receiving profile-member 460 which differs from the receiving profile-member according to FIG. 48a only in that, in the region of the vertical legs 472 and 474, folds 473 and 475 which extend in the longitudinal direction are provided. These serve to facilitate the technical shaping of the deformed portions 478. That is to say, the folds 473, 475 are intended to be considered in a manner of speaking as a “material reservoir” to allow the significant deformations in the region of the deformed portion 478 to be facilitated in terms of production complexity, without the wall thickness of the receiving profile-member 460 being excessively reduced or even locally destroyed.

As already indicated above, the individual configurations may also be combined with each other. In particular, the features for preventing the respective receiving profile-member from opening can be combined with features which bring about the tensioning effect which has been described several times above.

In principle, it is also possible to combine a plurality of profile-members of the substructure to form a single profile-member. For example, the configurations according to FIGS. 34 to 36 may be considered. It is thus possible to combine two receiving profile-members 294 according to FIG. 36 to form a single profile-member, two parallel material webs with parallel upper sides 296 which have corresponding recesses 298 being connected together by means of a connecting profile-member portion. Such a construction in which a plurality of receiving profile-members 296 which are connected together in a simple manner by means of a connecting profile-member portion are provided are to be subsumed in the appended patent claims.

The invention provides a simple yet reliable possibility for fitting large solar modules to a substructure in a secure manner without any risk of destruction during assembly.

1. Structure for fixing a large solar module to a substructure, comprising:
at least two retaining profile-members which can be fixed to a component from the solar module and substructure at the rear side, wherein the structure for fixing has at least two receiving profile-members which can be fixed to the other component from the solar module and substructure in a mutual relative position which corresponds to the relative position of the retaining profile-members, the retaining profile-member and the receiving profile-member having a mutually complementary profile shape so that the retaining profile-member can be received in a substantially positive-locking manner in the receiving profile-member, there being provided, on at least one pair comprising a mutually engaging retaining profile-member and receiving profile-member (50), mutually corresponding engagement formations (44, 54), by means of which the retaining profile-member (46) and the receiving profile-member engage with each other in a locking manner, wherein the engagement formations are at least partially inclined relative to a longitudinal axis of the receiving profile-member and the retaining profile-member so that the degree of mutual engagement is increased as the mutual engagement continues.

2. Fixing structure according to claim 1, wherein the retaining profile-member has a portion which tapers transversely relative to the longitudinal direction thereof and by means of which it can be inserted so as to be positioned in a corresponding widening portion of the retaining profile-member.

3. Fixing structure according to claim 2, wherein the retaining profile-member and the receiving profile-member are elongate and are each constructed in a w-shaped or trapezoidal manner in at least one portion.

4. Fixing structure according to claim 2, wherein the retaining profile-member and the receiving profile-member are each constructed as a circular profile-member in at least one portion.

5. Fixing structure according to claim 1, wherein the receiving profile-member has an undercut when viewed in a section orthogonal relative to the longitudinal direction and the retaining profile-member has a corresponding projection, the receiving profile-member being resiliently openable in such a manner that the retaining profile-member can be inserted in the receiving profile-member with resilient deformation, whereupon the projection and undercut engage one behind the other.

6. Fixing structure according to claim 5, wherein the receiving profile-member can be opened with an assembly tool.

7. Fixing structure according to claim 1, wherein the retaining profile-member is provided with at least one bead and in that the receiving profile-member is provided with at least one correspondingly arranged complementary bead which together form the engagement formation.

8. Fixing structure according to claim 7, wherein a plurality of directly adjacent beads and complementary beads form the engagement formation, the beads and complementary beads each individually describing a section of a cone surface.

9. Fixing structure according to claim 1, wherein the retaining profile-member is provided with recesses and flaps and in that the receiving profile-member is provided with correspondingly arranged complementary recesses and flaps which together form the engagement formation.

10. Fixing structure according to claim 1, wherein at least one component from the retaining profile-member and receiving profile-member is provided with notches and in that the other component from the retaining profile-member and receiving profile-member is provided with correspondingly arranged receiving regions which are in particular indented or constructed as a recess and which together form the engagement formation.

11. Fixing structure according to claim 10, wherein the notches are constructed in a hook-like, spoon-like or angular manner, the notches engaging in the receiving regions.

12. Fixing structure according to claim 11, wherein the receiving regions have a widened introduction portion for the notches and a fixing portion for securely retaining the notches.

13. Fixing structure according claim 1, wherein the path of the engagement formation is orientated in such an inclined manner that, when the solar module is assembled, the continuing mutual engagement is supported by the action of gravitational force.

14. Fixing structure according to claim 1, wherein at least one component from the retaining profile-member and receiving profile-member is provided with bolts, and in that the other component from the retaining profile-member and receiving profile-member is provided with correspondingly arranged receiving regions which together form the engagement formation.

15. Fixing structure according to claim 1, wherein the retaining profile-member is provided with local deformations and in that the receiving profile-member is provided with corresponding local deformations, the retaining profile-member in an assembly position being able to be inserted transversely relative to the longitudinal direction thereof, with a region of the local deformations thereof which protrudes transversely relative to the longitudinal direction thereof, in a region of the receiving profile-member which is accordingly opened transversely relative to the longitudinal direction thereof and, after a relative displacement between the retaining profile-member and the receiving profile-member in the longitudinal direction thereof, the protruding region of the retaining profile-member engaging in a positive-locking manner behind a recessed region of the receiving profile-member which receives it.

16. Fixing structure according to claim 15, wherein the retaining profile-member and the receiving profile-member are constructed as continuous profile-members in the region of the local deformations without interruption of the material.

17. Fixing structure according to claim 1, wherein ramp formations and/or stop elements are provided on the retaining profile-member and/or on the receiving profile-member and fix a predetermined positioning of the receiving profile-member and retaining profile-member relative to each other in the longitudinal direction of the profile-member and/or transversely relative to the longitudinal direction of the profile-member.

18. Fixing structure according to claim 1, wherein the component from the retaining profile-member and receiving profile-member that is fitted directly to the solar module is constructed so as to be longer in the longitudinal direction of the profile-member than the other component.

19. Fixing structure according to claim 1, wherein the component from the retaining profile-member and receiving profile-member that is fitted directly to the solar module is constructed with a smaller depth when viewed in the direction orthogonal relative to the solar module than the other component.

20. Fixing structure according to claim 1, wherein the retaining profile-member or receiving profile-member is fitted to the solar module by a heat-resistant adhesive layer, adhesive mass or an adhesive strip.

21. Fixing structure according to claim 20, wherein the adhesive layer has a minimum thickness of 2 mm and is constructed in a resilient manner.

22. Fixing structure according to claim 1, wherein each retaining profile-member and receiving profile-member is inclined relative to the horizontal.

23. Fixing structure according to claim 1, wherein individual retaining profile-member elements are arranged at the rear side of the solar module.

24. Fixing structure according to claim 23, wherein a retaining profile-member element has a head-like projection which extends away from the solar module and which can be received with an undercut in a complementary receiving profile-member.

25. Fixing structure according to claim 24, wherein the head-like projection is constructed so as to be rotationally symmetrical or so as to extend transversely relative to the direction of the projection.

26. Fixing structure according to claim 23, wherein a plurality of retaining profile-member elements are orientated in a linear manner relative to each other at the rear side of the solar module or are fitted to a common retaining profile-member rail.

27. Fixing structure according to claim 1, wherein the structure further comprises at least one gripping flap for engagement with a front side of a solar module.

28. Fixing structure according to claim 27, wherein the at least one gripping flap is arranged on the retaining profile-member.

29. Fixing structure according to claim 28, wherein the at least one gripping flap extends from a portion of the retaining profile-member that is fitted to the rear side of the solar module as far the front side and extends partially around it.

30. Fixing structure according to claim 28, wherein the at least one gripping flap extends from a portion of the retaining profile-member arranged so as to be remote from the rear side of the solar module as far as the front side and extends partially around it.

31. Fixing structure according to claim 1, wherein there are provided on the retaining profile-member or/and on the receiving profile-member local projections which provide a minimum spacing between the retaining profile-member and receiving profile-member.

32. Fixing structure according to claim 31, wherein the local projections are provided at the centre thereof with a recess, an abutment between the local projection and the portion of the retaining profile-member or receiving profile-member which engages therewith being produced in an annular edge region of the local projection which surrounds the recess.

33. Fixing structure according to claim 1, wherein the structure further comprises an electrical connector on the retaining profile-member and a complementary electrical connector on the receiving profile-member, the electrical connector and the complementary electrical connector being in a contacting state of engagement when the receiving profile-member and the retaining profile-member are in mutual engagement in a locking manner.

34. Retaining profile-member for a fixing structure according to claim 1.

35. Receiving profile-member for a fixing structure according to claim 1.

36. Substructure having a retaining profile-member according to claim 34.

37. Solar module comprising a fixing structure according to claim 1.

38. A substructure having a receiving profile-member according to claim 35.
